(19) United States
(12) Patent Application Publication
(10) Pub. No.: US 2026/0059917 A1
(43) Pub. Date: Feb. 26, 2026

(54) DISPLAY APPARATUS

(71) Applicant: LG Display Co., Ltd., Seoul (KR)

(72) Inventor: Yubin SIN, Paju-si (KR)

(73) Assignee: LG Display Co., Ltd., Seoul (KR)

(21) Appl. No.: 19/284,338

(22) Filed: Jul. 29, 2025

(30) Foreign Application Priority Data
Aug. 22, 2024 (KR) 10-2024-0112649

(51) Int. Cl. H10H 29/49; H10H 29/41

(52) U.S. Cl. CPC H10H 29/49; H10H 29/41

(57) ABSTRACT

A display apparatus includes a substrate including a display area, and a non-display, a buffer layer disposed on the substrate, a plurality of 1-1-th connection lines disposed on the buffer layer in the display area, a pixel drive circuit disposed on the plurality of 1-1-th connection lines and including a body, a plurality of circuit pads disposed on a bottom surface of the body, and a passivation film disposed to surround the body and the plurality of circuit pads, a plurality of bonding patterns configured to connect the plurality of 1-1-th connection lines and the plurality of circuit pads, a bank disposed on the pixel drive circuit, and a plurality of micro-LEDs disposed on the bank and electrically connected to the pixel drive circuit. Therefore, the layered structure is simplified, such that the flatness can be ensured, and a thin display apparatus can be implemented.

### CROSS-REFERENCE TO RELATED APPLICATIONS

This application claims priority to Korean Patent Application No. 10-2024-0112649, filed in the Republic of Korea on Aug. 22, 2024, in the Korean Intellectual Property Office, the entire disclosure of which is incorporated herein by reference.

### BACKGROUND

### Technical Field

The present disclosure relates to a display apparatus.

### Discussion of the Related Art

Display apparatuses are being applied to various electronic apparatuses such as TVs, mobile phones, notebook computers, and tablet computers.

As the display apparatuses, there are an organic light-emitting display (OLED) configured to autonomously emit, and a liquid crystal display (LCD) that requires a separate light source.

Recently, a display apparatus including a light-emitting diode (LED) has attracted attention as a next-generation display apparatus. Because the light-emitting diode is made of an inorganic material instead of an organic material, the light-emitting diode can be quickly turned on or off, have excellent luminous efficiency, and display high-luminance images in comparison with the liquid crystal display apparatus or the organic light-emitting display apparatus.

### SUMMARY OF THE DISCLOSURE

An object to be achieved by the present disclosure is to provide a display apparatus implemented as a thin display apparatus.

Another object to be achieved by the present disclosure is to provide a display apparatus that implements process optimization by reducing process costs and time.

Still another object to be achieved by the present disclosure is to provide a display apparatus with improved flatness.

Yet another object to be achieved by the present disclosure is to provide a display apparatus that suppresses a defect caused by foreign substances.

Objects of the present disclosure are not limited to the above-mentioned objects, and other objects, which are not mentioned above, can be clearly understood by those skilled in the art from the following descriptions.

A display apparatus according to one or more embodiments of the present disclosure includes: a substrate including a display area and a non-display area configured to surround the display area; a buffer layer disposed on the substrate; a plurality of 1-1-th connection lines disposed on the buffer layer in the display area; a pixel drive circuit disposed on the plurality of 1-1-th connection lines and including a body, a plurality of circuit pads disposed on a bottom surface of the body, and a passivation film disposed to surround the body and the plurality of circuit pads; a plurality of bonding patterns configured to connect the plurality of 1-1-th connection lines and the plurality of circuit pads; a bank disposed on the pixel drive circuit; and a plurality of micro-light emitting diodes (micro-LEDs) disposed on the bank and electrically connected to the pixel drive circuit. Therefore, the layered structure is simplified, such that the flatness can be ensured, and a thin display apparatus can be implemented.

Other detailed matters of the example embodiments of the present disclosure are included in the detailed description and the drawings.

According to aspects of the present disclosure, the pixel drive circuit is disposed on the connection line and bonded by diffusion bonding, such that the pixel drive circuit can be fixed onto the connection line and electrically connected to the connection line.

According to aspects of the present disclosure, a bonding layer for bonding or fixing the pixel drive circuit is excluded, which can reduce the process costs and time and implement the process optimization.

According to aspects of the present disclosure, the bonding layer is excluded, which can minimize a defect caused when unnecessary foreign substances are attached to the bonding layer.

According to aspects of the present disclosure, the connection line disposed below the pixel drive circuit is utilized as an alignment key, and a separate process of forming the alignment key for aligning the position of the pixel drive circuit is excluded, which can reduce the process costs and time and implement the process optimization.

According to aspects of the present disclosure, the plurality of connection lines are disposed to be spaced apart from one another based on the pixel drive circuit, and an additional protective layer or insulation layer for disposing the plurality of connection lines is excluded, which can reduce the process costs and time and implement the process optimization.

According to aspects of the present disclosure, the bonding layer and the additional protective layer are excluded, which can simplify the layered structure of the display apparatus, ensure the flatness of the upper portion of the display apparatus, and implement a thin display apparatus.

The effects according to the present disclosure are not limited to the contents exemplified above, and include, for example, more various effects further explained in the DETAILED DESCRIPTION section below.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is an exploded perspective view of a display apparatus according to an embodiment of the present disclosure;

FIG. 2 is a top plan view of the display apparatus according to the embodiment of the present disclosure;

FIG. 3 is an enlarged view of the display apparatus according to the embodiment of the present disclosure;

FIG. 4 is a view illustrating a circuit structure according to the embodiment of the present disclosure;

FIG. 5 is a top plan view of the display apparatus according to the embodiment of the present disclosure;

FIG. 6 is a top plan view of the display apparatus according to the embodiment of the present disclosure;

FIG. 7 is a top plan view of the display apparatus according to the embodiment of the present disclosure;

FIG. 8 is a cross-sectional view taken along line VIII-VIII′ in FIG. 3;

FIGS. 9A and 9B are enlarged views for explaining a process of joining a pixel drive circuit and a 1-1-th connection line of the display apparatus according to the embodiment of the present disclosure;

FIG. 10 is a cross-sectional view of the display apparatus according to the embodiment of the present disclosure;

FIG. 11 is a cross-sectional view of a display apparatus according to another embodiment of the present disclosure;

FIGS. 12A and 12B are enlarged views for explaining a process of joining a pixel drive circuit and a 1-1-th connection line of the display apparatus according to the another embodiment of the present disclosure;

FIG. 13 is a cross-sectional view of a display apparatus according to still another embodiment of the present disclosure;

FIGS. 14A and 14B are enlarged views for explaining a process of joining a pixel drive circuit and a 1-1-th connection line of the display apparatus according to still another embodiment of the present disclosure; and

FIGS. 15 to 18 are views illustrating apparatuses to which the display apparatus according to the embodiments of the present disclosure are applied.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When explaining temporal relationships, terms such as “after,” “following,” “subsequent to,” or “before,” etc., can include non-consecutive cases unless terms like “immediately” or “directly” are used.

Terms such as “first,” “second,” etc. are used to describe various components, but these components are not limited by these terms. These terms are merely used to distinguish one component from another. Therefore, a first component mentioned herein could be a second component within the technical scope of the present disclosure.

In describing the components of the present disclosure, terms such as first, second, A, B, (a), or (b) can be used. These terms are only intended to distinguish that one component from other components, and the nature, order, sequence, or number of the respective component is not limited by these terms.

When a component is described as being “connected,” “coupled,” “joined,” or “attached” to another component, it should be understood that the component can be directly connected, coupled, joined, or attached to the other component, but unless explicitly specified otherwise, it can also be indirectly connected, coupled, joined, or attached with another component intervening between each component.

When a component or layer is described as being “in contact with” or “overlapping” another component or layer, the component or layer can directly contact or overlap the other component or layer, but unless explicitly specified otherwise, it should be understood that it can also indirectly contact or overlap with another component intervening between each component.

The term “at least one” should be understood to include all combinations of one or more of the associated components. For example, “at least one of first, second, and third components” means not only the first, second, or third component, but also includes all combinations of two or more components from among the first, second, and third components.

The terms “first direction”, “second direction”, “third direction”, “X-axis direction”, “Y-axis direction”, and “Z-axis direction” should not be interpreted solely as geometric relationships perpendicular to each other, but can indicate broader directionality within the range where the configuration of the present disclosure can function. Further, the term “can” fully encompasses all the meanings and coverages of the term “may.”

The features of various embodiments in the present disclosure can be partially or wholly combined or associated with each other, various technical interlocking and operations are possible, and each embodiment can be implemented independently of each other or can be implemented together in an associated relationship.

Hereinafter, example embodiments of the present disclosure will be described in detail with reference to the drawings. All the components of each display apparatus/device according to all embodiments of the present disclosure are operatively coupled and configured.

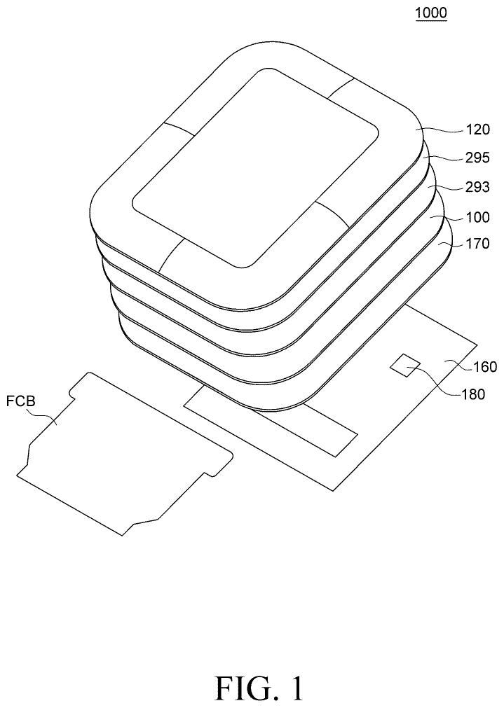

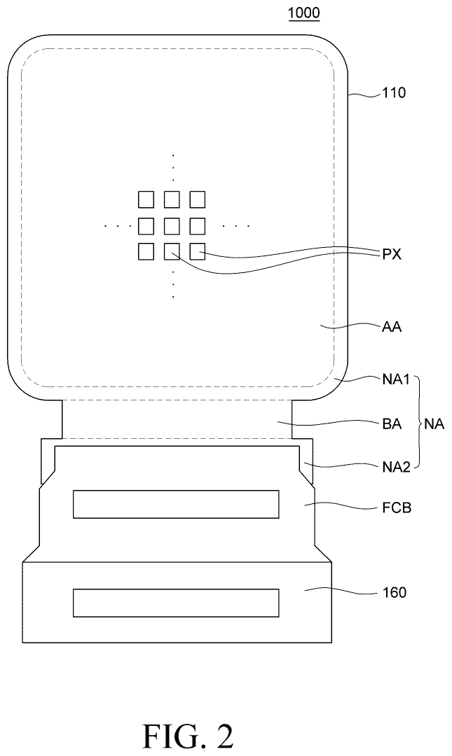

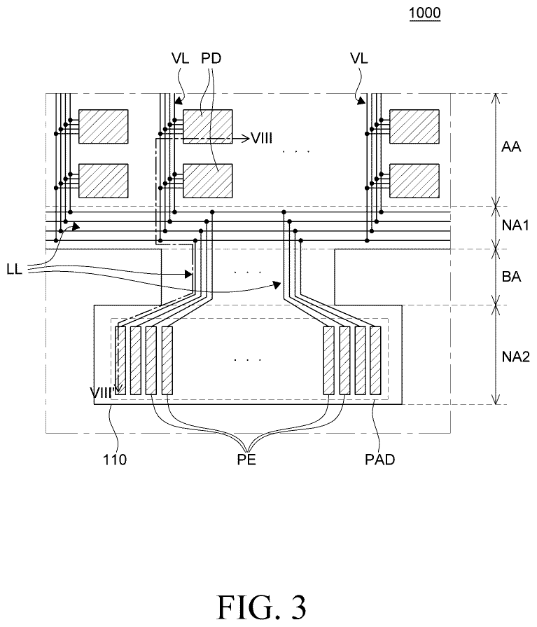

FIG. 1 is a perspective view illustrating a display apparatus according to an embodiment of the present disclosure. FIG. 2 is a top plan view of the display apparatus according to the embodiment of the present disclosure. FIG. 3 is an enlarged view of the display apparatus according to the embodiment of the present disclosure.

With reference to FIGS. 1 to 3, a display apparatus 1000 according to an embodiment of the present disclosure can include a display panel 100, a polarizing layer 293, a bonding layer 295, a cover member 120, a support substrate 170, a flexible circuit board FCB, and a printed circuit board 160.

For example, the display panel 100 of the display apparatus 1000 can include a substrate 110. The substrate 110 can be a member configured to support other constituent elements of the display apparatus 1000. The substrate 110 can be made of an insulating material. For example, the substrate 110 can be made of glass, resin, or the like. In addition, the substrate 110 can be made of a material having flexibility. For example, the substrate 110 can be made of an organic insulating material that is a plastic material, such as polyimide (PI), having flexibility. However, the embodiments of the present disclosure are not limited thereto.

The display panel 100 can implement information, videos, and/or images to be provided to a user. For example, the display panel 100 can include a display area (or active area) AA and a non-display area (or non-active area) NA. For example, the substrate 110 can include the display area AA and the non-display area NA. The display area AA and the non-display area NA may not be described as being limited to the substrate 110, but the display area AA and the non-display area NA can be described for the entire display apparatus 1000.

The display area AA can be an area in which images are displayed. The display area AA can include a plurality of pixels PX. The plurality of pixels PX can each include a plurality of subpixels. A plurality of micro-light emitting diodes (micro-LEDs) can be respectively disposed in the plurality of subpixels.

The non-display area NA can be an area in which no image is displayed. Various lines and circuits for operating the plurality of pixels PX in the display area AA can be disposed in the non-display area NA. For example, various types of lines and drive circuits can be mounted in the non-display area NA, and a pad part PAD, to which an integrated circuit, a printed circuit, and the like are connected, can be disposed. However, the embodiments of the present disclosure are not limited thereto.

For example, the drive circuits can be a data drive circuit and/or a gate drive circuit. However, the embodiments of the present disclosure are not limited thereto. Lines for supplying control signals for controlling the drive circuits can be disposed. For example, the control signals can include various types of timing signals including clock signals, input data enable signals, and synchronizing signals. However, the embodiments of the present disclosure are not limited thereto. The control signal can be received through the pad part PAD. For example, link lines LL for transmitting signals can be disposed in the non-display area NA. For example, drive components, such as a flexible circuit board FCB and the printed circuit board 160, can be connected to the pad part PAD.

According to the present disclosure, the non-display area NA can include a first non-display area NA1, a bending area BA, and a second non-display area NA2. For example, the first non-display area NA1 can be an area that surrounds at least a part of the display area AA. The bending area BA can be a bendable area extending from at least any one of a plurality of sides of the first non-display area NA1. The second non-display area NA2 can be an area extending from the bending area BA, and the pad part PAD can be disposed in the second non-display area NA2. For example, the bending area BA can be in a curved state, and the remaining area of the substrate 110, except for the bending area BA, can be in a flat state. In this case, as the bending area BA is curved, the second non-display area NA2 can be positioned on a rear surface of the display area AA. However, the embodiments of the present disclosure are not limited thereto.

The display area AA of the substrate 110 or the display apparatus 1000 can have various shapes in accordance with the design of the display apparatus 1000. For example, the display area AA can have a rectangular shape having four corners with round shapes. However, the embodiments of the present disclosure are not limited thereto. In another example, the display area AA can have a circular shape or a rectangular shape having four corners with right-angled shapes. However, the embodiments of the present disclosure are not limited thereto.

According to the present disclosure, a width of the second non-display area NA2 in which a plurality of pad electrodes PE is disposed can be larger than a width of the bending area BA in which only the plurality of link lines LL is disposed. In addition, a width of the display area AA in which the plurality of subpixels are disposed can be larger than a width of the bending area BA in which the plurality of link lines LL is disposed. The drawing illustrates that the width of the bending area BA can be smaller than a width of another area of the substrate 110. However, the shape of the substrate 110 including the bending area BA is illustrative, and the embodiments of the present disclosure are not limited thereto.

With reference to FIG. 3, a plurality of pixel drive circuits PD can be disposed in the display area AA. The plurality of pixel drive circuits PD can be circuits for operating the micro-LEDs of the plurality of subpixels. The plurality of pixel drive circuits PD can each include a plurality of transistors including a driving transistor, and a plurality of storage capacitors. The plurality of pixel drive circuits PD can control light-emitting operations of the plurality of micro-LEDs by supplying control signals, power, and drive currents to the micro-LEDs of the plurality of subpixels. For example, the pixel drive circuit PD can include a power line, and a signal line for controlling light-emitting on/off operations and/or light emission time of the micro-LED. For example, the plurality of pixel drive circuits PD can be operation drivers manufactured on a semiconductor substrate by using a metal-oxide-silicon field effect transistor (MOSFET) manufacturing process. However, the embodiments of the present disclosure are not limited thereto. The operation driver can include the plurality of pixel drive circuits PD and operate the plurality of subpixels.

With reference to FIG. 1 together, the flexible circuit board FCB and the printed circuit board 160 can be disposed below the display panel 100. The flexible circuit board FCB and the printed circuit board 160 can be disposed at least at one side edge of the display panel 100. However, the embodiments of the present disclosure are not limited thereto. One side of the flexible circuit board FCB can be attached to the display panel 100, and the other side of the flexible circuit board FCB can be attached to the printed circuit board 160. However, the embodiments of the present disclosure are not limited thereto. The flexible circuit board FCB can be a flexible film. However, the embodiments of the present disclosure are not limited thereto.

The pad part PAD including the plurality of pad electrodes PE can be disposed in the second non-display area NA2. The drive components including one or more flexible circuit boards (or flexible films) FCB and the printed circuit board 160 can be attached or bonded to the pad part PAD. The plurality of pad electrodes PE of the pad part PAD can be electrically connected to one or more flexible circuit boards (or flexible films) FCB and transmit various types of signals (or power) to the plurality of pixel drive circuits PD in the display area AA from the printed circuit board 160 and the flexible circuit board (or flexible film) FCB.

The flexible circuit board (or flexible film) FCB can be a film having various types of components disposed on a base film having flexibility. For example, a drive IC, such as a gate driver IC or a data driver IC, can be disposed on the flexible circuit board (or flexible film) FCB. However, the embodiments of the present disclosure are not limited thereto. The drive IC can be a component configured to process data and driving signals for displaying images. The drive IC can be disposed in ways such as a chip-on-glass (COG) method, a chip-on-film (COF) method, or a tape carrier package (TCP) method depending on how the drive IC is mounted. However, the embodiments of the present disclosure are not limited thereto. The flexible circuit board (or flexible film) FCB can be attached or bonded to the plurality of pad electrodes PE by means of a conductive bonding layer. However, the embodiments of the present disclosure are not limited thereto.

The printed circuit board 160 can be a component electrically connected to one or more flexible circuit boards (or flexible films) FCB and configured to supply a signal to the drive IC. The printed circuit board 160 can be disposed at one side of the flexible circuit board (or flexible film) FCB and electrically connected to the flexible circuit board (or flexible film) FCB. Various types of components for supplying various signals to the drive IC can be disposed on the printed circuit board 160. For example, various components, such as a timing controller, a power source, a memory, or a processor, can be disposed on the printed circuit board 160. For example, the printed circuit board 160 can include a power management integrated circuit (PMIC). However, the embodiments of the present disclosure are not limited thereto.

The printed circuit board 160 can include at least one hole 180. However, the embodiments of the present disclosure are not limited thereto. Internal components can be disposed in an area corresponding to at least one hole 180 and detect ambient light, a temperature, or the like that can be provided to the plurality of sensors. For example, the internal components can include an ambient light sensor (ALS), a temperature sensor, or the like. However, the embodiments of the present disclosure are not limited thereto. For example, the hole 180 can be a transmission hole or the like. However, the embodiments of the present disclosure are not limited thereto.

With reference to FIG. 1, the polarizing layer 293 can be disposed on the display panel 100. The polarizing layer 293 can suppress or reduce a situation in which light generated from the external light source is introduced into the display panel 100 and affects the micro-LED or the like.

The cover member 120 can be disposed on the polarizing layer 293. The cover member 120 can be a member for protecting the display panel 100. The bonding layer 295 can be disposed between the polarizing layer 293 and the cover member 120. The cover member 120 can be attached to the display panel 100 by using the bonding layer 295. The bonding layer 295 can include an optically clear adhesive (OCA), an optically clear resin (OCR), a pressure-sensitive adhesive (PSA), or the like. However, the embodiments of the present disclosure are not limited thereto.

The support substrate 170 can be disposed between the display panel 100 and the printed circuit board 160. The support substrate 170 can reinforce the rigidity of the display panel 100. The support substrate 170 can be a backplate. However, the embodiments of the present disclosure are not limited thereto.

With reference to FIGS. 1 to 3, the plurality of link lines LL can be disposed in the non-display area NA. The plurality of link lines LL can be lines configured to transmit various types of signals to the display area AA from one or more flexible circuit boards (or flexible films) FCB and the printed circuit board 160. The plurality of link lines LL can extend from the plurality of pad electrodes PE of the second non-display area NA2 toward the bending area BA and the first non-display area NA1 and be electrically connected to a plurality of drive lines VL in the display area AA. The plurality of pixel drive circuits PD can operate by receiving signals from one or more flexible circuit boards (or flexible films) FCB and the printed circuit board 160 through the drive lines VL in the display area AA and the link lines LL in the non-display area NA.

For example, the plurality of drive lines VL can be lines configured to transmit signals, which are outputted from the flexible circuit board (or flexible film) FCB and the printed circuit board 160, to the plurality of pixel drive circuits PD together with the plurality of link lines LL. The plurality of drive lines VL can be disposed in the display area AA and respectively electrically connected to the plurality of pixel drive circuits PD. The plurality of drive lines VL can extend from the display area AA toward the non-display area NA and be electrically connected to the plurality of link lines LL. Therefore, the signals outputted from the flexible circuit board (or flexible film) FCB and the printed circuit board 160 can be transmitted to the plurality of pixel drive circuits PD through the plurality of link lines LL and the plurality of drive lines VL.

When the bending area BA is bent, the plurality of link lines LL can also be partially bent. Stress can be concentrated on a part of the bent link line LL, and therefore, the link line LL can crack. Therefore, the plurality of link lines LL can be made of an electrically conductive material that is excellent in flexibility in order to reduce the occurrence of a crack when the bending area BA is bent. For example, the plurality of link lines LL can be made of an electrically conductive material, such as gold (Au), silver (Ag), or aluminum (Al), that is excellent in flexibility. However, the embodiments of the present disclosure are not limited thereto. In addition, the plurality of link lines LL can be made of one of various electrically conductive materials used for the display area AA. For example, the plurality of link lines LL can be made of molybdenum (Mo), chromium (Cr), titanium (Ti), nickel (Ni), neodymium (Nd), copper (Cu), and an alloy of silver (Ag) and magnesium (Mg), or an alloy thereof. However, the embodiments of the present disclosure are not limited thereto. The plurality of link lines LL can have a multilayer structure including various electrically conductive material. For example, the plurality of link lines LL can have a triple layer structure made of titanium (Ti), aluminum (Al), and titanium (Ti). However, the embodiments of the present disclosure are not limited thereto.

The plurality of link lines LL can have various shapes to reduce stress. At least a part of each of the plurality of link lines LL disposed in the bending area BA can extend in a direction identical to an extension direction of the bending area BA or extend in a direction different from the extension direction of the bending area BA to reduce stress. For example, in case that the bending area BA extends in one direction from the first non-display area NA1 toward the second non-display area NA2, at least a part of the link line LL disposed in the bending area BA can extend in a direction inclined with respect to one direction. In another example, at least a part of each of the plurality of link lines LL can have patterns with various shapes. For example, at least a part of each of the plurality of link lines LL disposed in the bending area BA can have a shape in which conductive patterns are repeatedly disposed and have at least one of a diamond shape, a rhombic shape, a trapezoidal wave shape, a triangular wave shape, a serrated wave shape, a sine wave shape, a circular shape, and an omega (Ω) shape. However, the embodiments of the present disclosure are not limited thereto. Therefore, in order to minimize stress concentrated on the plurality of link lines LL and minimize the occurrence of a crack caused by the stress, the plurality of link lines LL can have various shapes including the above-mentioned shapes. However, the embodiments of the present disclosure are not limited thereto.

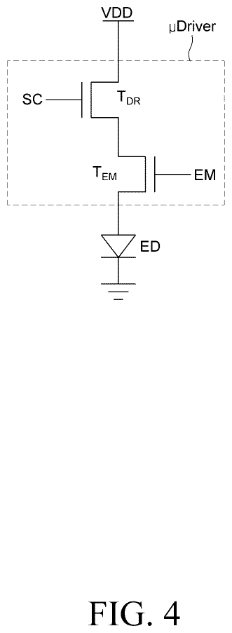

FIG. 4 is a view illustrating a circuit structure according to the embodiment of the present disclosure.

The pixel drive circuit PD can include a micro-driver μDriver. A micro-LED ED can be electrically connected to the micro-driver μDriver of the pixel drive circuit PD and operated. FIG. 4 illustrates that one micro-LED ED is connected to the micro-driver μDriver. However, the present disclosure is not limited thereto. For example, eight micro-LEDs ED can be connected to one micro-driver μDriver. In another example, sixteen micro-LEDs ED can be connected to one micro-driver μDriver, or thirty-two micro-LEDs ED or sixty-four micro-LEDs ED can be simultaneously connected to one micro-driver μDriver.

Referring to FIG. 4, one micro-driver μDriver can include a driving transistor T_{DR} and a light-emitting transistor T_{EM}. However, the embodiments of the present disclosure are not limited thereto.

For example, a high-potential power voltage VDD can be applied to a first electrode of the driving transistor T_{DR}, a first electrode of the light-emitting transistor T_{EM} can be connected to a second electrode of the driving transistor T_{DR}, and a scan signal SC can be applied to a gate electrode of the driving transistor T_{DR}. The scan signal SC applied to the gate electrode of the driving transistor T_{DR} can be direct current power, and a fixed reference voltage can be applied for each frame. However, the embodiments of the present disclosure are not limited thereto.

The second electrode of the driving transistor T_{DR} can be connected to the first electrode of the light-emitting transistor T_{EM}, the micro-LED ED can be connected to a second electrode of the light-emitting transistor T_{EM}, and a light emission signal EM can be applied to a gate electrode of the light-emitting transistor T_{EM}. The light emission signal EM applied to the gate electrode of the light-emitting transistor T_{EM} can be a pulse width modulation signal that changes for each frame. However, the embodiments of the present disclosure are not limited thereto.

A first electrode of the micro-LED ED can be connected to the second electrode of the light-emitting transistor T_{EM}, and a second electrode of the micro-LED ED can be connected to the ground. For example, the first electrode can be an anode electrode, and the second electrode can be a cathode electrode. However, the embodiments of the present disclosure are not limited thereto.

The driving transistor T_{DR} and the light-emitting transistor T_{EM} can each be an n-type transistor or a p-type transistor.

The driving transistor T_{DR} can be turned on by the scan signal SC applied from a timing controller to the micro-driver μDriver, and the light-emitting transistor T_{EM} can be turned on by the light emission signal EM. Therefore, the drive current is applied to the micro-LED ED via the driving transistor T_{DR} and the light-emitting transistor T_{EM} by the high-potential power voltage VDD applied to the first electrode of the driving transistor T_{DR}, such that the micro-LED ED can emit light.

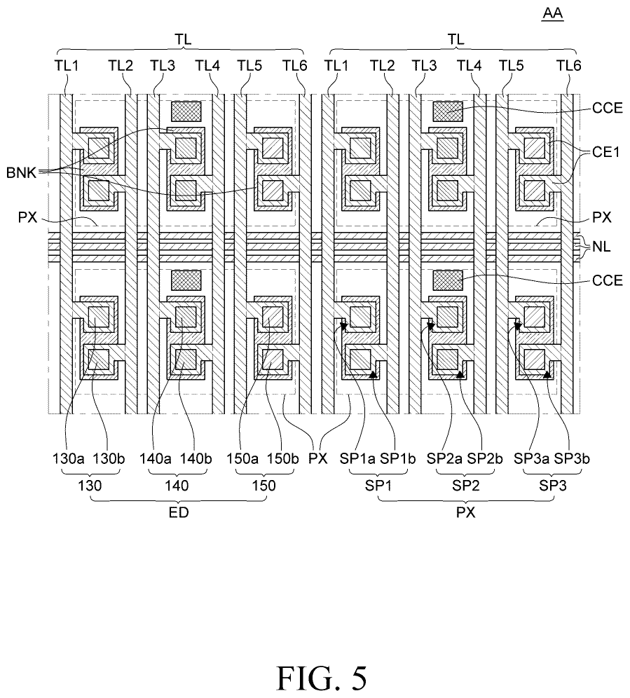

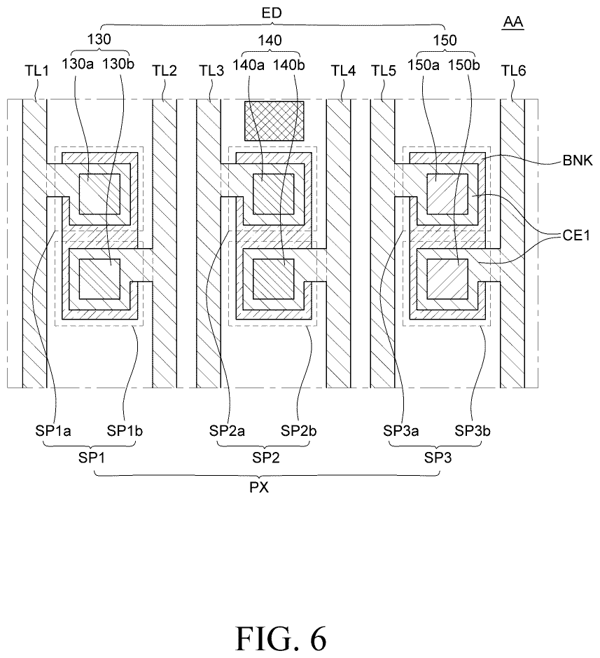

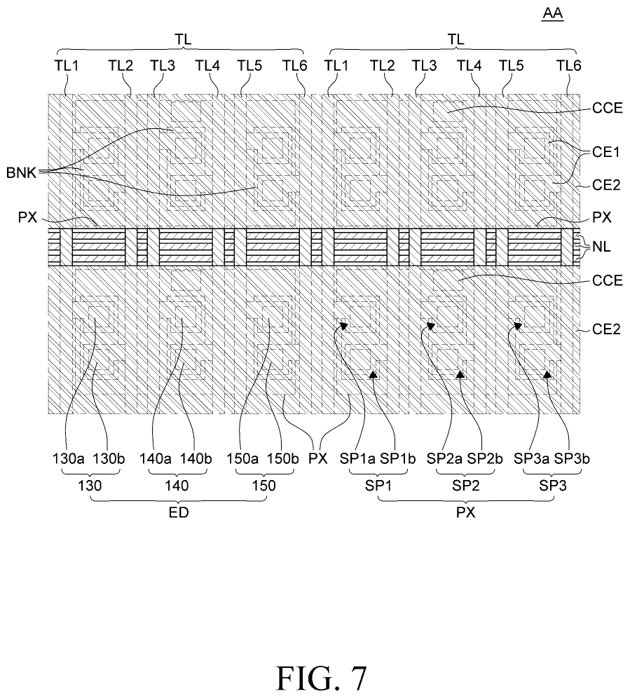

FIGS. 5 to 7 are top plan views of the display apparatus according to the embodiment of the present disclosure. For example, FIG. 5 is an enlarged top plan view of a display area including a plurality of pixels. FIG. 6 is an enlarged top plan view of a display area including a single pixel. FIG. 7 is an enlarged top plan view of a display area including a plurality of pixels. FIGS. 5 and 6 illustrate a plurality of signal lines TL, a plurality of communication lines NL, a plurality of first electrodes CE1, a plurality of banks BNK, and a plurality of micro-LEDs ED. However, the embodiments of the present disclosure are not limited thereto. FIG. 7 is an enlarged top plan view illustrating a state in which a plurality of second electrodes CE2 are additionally disposed in FIG. 5.

With reference to FIGS. 5 and 6, the plurality of pixels PX including the plurality of subpixels can be disposed in the display area AA. The plurality of subpixels can each include the micro-LED ED and emit light independently. The plurality of subpixels can be disposed in a plurality of rows and a plurality of columns while defining a matrix shape. However, the embodiments of the present disclosure are not limited thereto.

The plurality of subpixels can include a first subpixel SP1, a second subpixel SP2, and a third subpixel SP3. For example, any one of the first subpixel SP1, the second subpixel SP2, and the third subpixel SP3 can be a red subpixel, another subpixel can be a green subpixel, and the remaining subpixel can be a blue subpixel. The types of plurality of subpixels are illustrative. However, the embodiments of the present disclosure are not limited thereto.

The plurality of pixels PX can each include one or more first subpixels SP1, one or more second subpixels SP2, and one or more third subpixels SP3. For example, one pixel PX can include a pair of first subpixels SP1, a pair of second subpixels SP2, and a pair of third subpixels SP3. The pair of first subpixels SP1 can include a 1-1-th subpixel SPla and a 1-2-th subpixel SP1b. The pair of second subpixels SP2 can include a 2-1-th subpixel SP2a and a 2-2-th subpixel SP2b. The pair of third subpixels SP3 can include a 3-1-th subpixel SP3a and a 3-2-th subpixel SP3b. For example, one pixel PX can include the 1-1-th subpixel SP1a, the 1-2-th subpixel SP1b, the 2-1-th subpixel SP2a, the 2-2-th subpixel SP2b, the 3-1-th subpixel SP3a, and the 3-2-th subpixel SP3b. However, the embodiments of the present disclosure are not limited thereto.

The plurality of subpixels constituting one pixel PX can be variously arranged. For example, in one pixel PX, the pair of first subpixels SP1 can be disposed in the same column, the pair of second subpixels SP2 can be disposed in the same column, and the pair of third subpixels SP3 can be disposed in the same column. The first subpixel SP1, the second subpixel SP2, and the third subpixel SP3 can be disposed in the same row. The number of and arrangement of the plurality of subpixels constituting one pixel PX are illustrative. However, the embodiments of the present disclosure are not limited thereto.

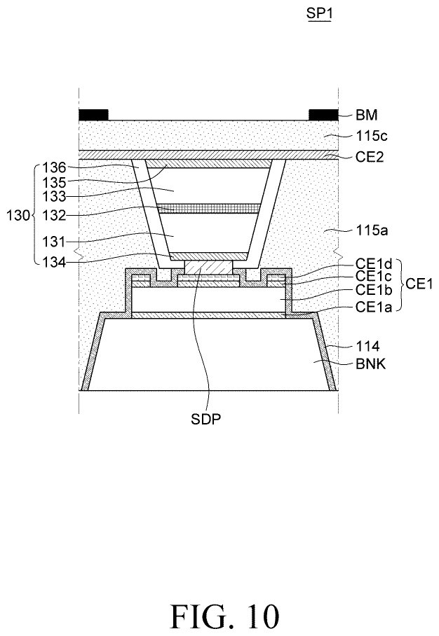

The plurality of signal lines TL can be disposed in areas between the plurality of subpixels. The plurality of signal lines TL can extend in the column direction between the plurality of subpixels. The plurality of signal lines TL can be lines configured to transmit an anode voltage from the pixel drive circuit PD to the plurality of subpixels. For example, the plurality of signal lines TL can be electrically connected to the plurality of pixel drive circuits PD and the first electrodes CE1 of the plurality of subpixels. The anode voltage outputted from the pixel drive circuit PD can be transmitted to the first electrodes CE1 of the plurality of subpixels through the plurality of signal lines TL. For example, the first electrode CE1 can be an electrode electrically connected to an anode electrode 134 (see for example FIG. 10) of the micro-LED ED. Therefore, the anode voltage from the signal line TL can be transmitted to the anode electrode 134 of the micro-LED ED through the first electrode CE1.

Therefore, the structure of the display apparatus 1000 can be simplified by using the pixel drive circuit PD into which a plurality of pixel circuits is integrated instead of forming a plurality of transistors and a plurality of storage capacitors in the plurality of subpixels. In addition, because the circuits respectively disposed in the plurality of subpixels are integrated into one pixel drive circuit PD, the high-efficiency operation with low power consumption can be performed.

The plurality of signal lines TL can include first signal lines TL1, second signal lines TL2, third signal lines TL3, fourth signal lines TL4, fifth signal lines TL5, and sixth signal lines TL6. The first signal line TL1 and the second signal line TL2 can each be electrically connected to each of the pair of first subpixels SP1. The third signal line TL3 and the fourth signal line TL4 can each be electrically connected to each of the pair of second subpixels SP2. The fifth signal line TL5 and the sixth signal line TL6 can each be electrically connected to each of the pair of third subpixels SP3.

The first signal line TL1 can be disposed at one side of the pair of first subpixels SP1, and the second signal line TL2 can be disposed at the other side of the pair of first subpixels SP1. The first signal line TL1 can be electrically connected to one of the pair of first subpixels SP1, e.g., the first electrode CE1 of the 1-1-th subpixel SPla. The second signal line TL2 can be electrically connected to the remaining one of the pair of first subpixels SP1, e.g., the first electrode CE1 of the 1-2-th subpixel SP1b.

The third signal line TL3 can be disposed at one side of the pair of second subpixels SP2, and the fourth signal line TL4 can be disposed at the other side of the pair of second subpixels SP2. For example, the third signal line TL3 can be disposed adjacent to the second signal line TL2. The third signal line TL3 can be electrically connected to one of the pair of second subpixels SP2, e.g., the first electrode CE1 of the 2-1-th subpixel SP2a. The fourth signal line TL4 can be electrically connected to the remaining one of the pair of second subpixels SP2, e.g., the first electrode CE1 of the 2-2-th subpixel SP2b.

The fifth signal line TL5 can be disposed at one side of the pair of third subpixels SP3, and the sixth signal line TL6 can be disposed at the other side of the pair of third subpixels SP3. For example, the fifth signal line TL5 can be disposed adjacent to the fourth signal line TL4. The sixth signal line TL6 can be disposed adjacent to the first signal line TL1 connected to the adjacent pixel PX. The fifth signal line TL5 can be electrically connected to one of the pair of third subpixels SP3, e.g., the first electrode CE1 of the 3-1-th subpixel SP3a. The sixth signal line TL6 can be electrically connected to the remaining one of the pair of third subpixels SP3, e.g., the first electrode CE1 of the 3-2-th subpixel SP3b.

The plurality of signal lines TL can be made of an electrically conductive material. For example, the plurality of signal lines TL can be made of an electrically conductive material such as titanium (Ti), aluminum (Al), copper (Cu), molybdenum (Mo), nickel (Ni), chromium (Cr), indium tin oxide (ITO), indium zinc oxide (IZO), or indium gallium zinc oxide (IGZO). However, the embodiments of the present disclosure are not limited thereto. In another example, the plurality of signal lines TL can have a multilayer structure made of an electrically conductive material. For example, the plurality of signal lines TL can have a multilayer structure made of titanium (Ti), aluminum (Al), titanium (Ti), and indium tin oxide (ITO). However, the embodiments of the present disclosure are not limited thereto.

The plurality of communication lines NL can be disposed in areas between the plurality of pixels PX. The plurality of communication lines NL can be disposed to extend in the row direction in the areas between the plurality of pixels PX. The plurality of communication lines NL can be disposed in the areas between the plurality of second electrodes CE2 and may not overlap the plurality of second electrodes CE2. For example, the plurality of communication lines NL can be lines used for short-range communication such as near field communication (NFC). The plurality of communication lines NL can serve as antennas. For example, the plurality of communication lines NL can be a plurality of connection lines and the like. However, the embodiments of the present disclosure are not limited thereto.

According to the present disclosure, the bank BNK can be disposed in each of the plurality of subpixels. The plurality of banks BNK can have structures on which the plurality of micro-LEDs ED is seated. The plurality of banks BNK can guide positions of the plurality of micro-LEDs ED during the process of transferring the plurality of micro-LEDs ED to the display apparatus 1000. The plurality of micro-LEDs ED can be transferred onto the plurality of banks BNK during the process of transferring the plurality of micro-LEDs ED. The plurality of banks BNK can be bank patterns, structures, or the like. However, the embodiments of the present disclosure are not limited thereto.

The bank BNK of the first subpixel SP1, the bank BNK of the second subpixel SP2, and the bank BNK of the third subpixel SP3 can be disposed to be spaced apart from one another. The bank BNK of the first subpixel SP1, the bank BNK of the second subpixel SP2, and the bank BNK of the third subpixel SP3 can be configured to be separated from one another. Therefore, the banks BNK of the first subpixel SP1, the second subpixel SP2, and the third subpixel SP3, to which different types of micro-LEDs ED are transferred, can be easily identified.

The bank BNK of the 1-1-th subpixel SPla and the bank BNK of the 1-2-th subpixel SP1b can be connected to each other, spaced apart from each other, or separated from each other. For example, the bank BNK of the 1-1-th subpixel SPla and the bank BNK of the 1-2-th subpixel SP1b, on which the micro-LEDs ED of the same type are disposed, can be connected to each other, spaced apart from each other, or separated from each other in consideration of designs such as transfer process requirements. Further, the bank BNK of the 2-1-th subpixel SP2a and the bank BNK of the 2-2-th subpixel SP2b can be connected to each other, spaced apart from each other, or separated from each other. The bank BNK of the 3-1-th subpixel SP3a and the bank BNK of the 3-2-th subpixel SP3b can be connected to each other, spaced apart from each other, or separated from each other. Therefore, the banks BNK of the pair of first subpixels SP1, the banks BNK of the pair of second subpixels SP2, and the banks BNK of the pair of third subpixels SP3 can be variously formed. However, the embodiments of the present disclosure are not limited thereto.

For example, the plurality of banks BNK can be made of an organic insulating material. The plurality of banks BNK can each be configured as a single layer or multilayer made of an organic insulating material. For example, the plurality of banks BNK can be made of photoresist, polyimide (PI), an acrylic material, or the like. However, the embodiments of the present disclosure are not limited thereto.

The first electrode CE1 can be disposed in each of the plurality of subpixels. The first electrode CE1 can be disposed on the bank BNK. The first electrode CE1 can be electrically connected to one of the plurality of signal lines TL. At least a part of the first electrode CE1 can extend to the outside of the bank BNK and be electrically connected to the signal line TL closest to the first electrode CE1. For example, a part of the first electrode CE1 of the 1-1-th subpixel SPla can extend to one side area of the 1-1-th subpixel SPla and be electrically connected to the first signal line TL1, and a part of the first electrode CE1 of the 1-2-th subpixel SP1b can extend to the other side area of the 1-2-th subpixel SP1b and be electrically connected to the second signal line TL2. A part of the first electrode CE1 of the 2-1-th subpixel SP2a can extend to one side area of the 2-1-th subpixel SP2a and be electrically connected to the third signal line TL3, and a part of the first electrode CE1 of the 2-2-th subpixel SP2b can extend to the other side area of the 2-2-th subpixel SP2b and be electrically connected to the fourth signal line TL4. A part of the first electrode CE1 of the 3-1-th subpixel SP3a can extend to one side area of the 3-1-th subpixel SP3a and be electrically connected to the fifth signal line TL5, and a part of the first electrode CE1 of the 3-2-th subpixel SP3b can extend to the other side area of the 3-2-th subpixel SP3b and be electrically connected to the sixth signal line TL6.

The first electrode CE1 can be electrically connected to the anode electrode 134 of the micro-LED ED and transmit the anode voltage from the pixel drive circuit PD to the micro-LED ED through the signal line TL. Different voltages can be applied to the first electrode CE1 of each of the plurality of subpixels in accordance with the displayed images. For example, different voltages can be applied to the first electrode CE1 of each of the plurality of subpixels. Therefore, the first electrode CE1 can be a pixel electrode. However, the embodiments of the present disclosure are not limited thereto.

The first electrode CE1 can be made of an electrically conductive material. For example, the first electrode CE1 can be integrated with the plurality of signal lines TL. For example, the first electrode CE1 can be made of the same electrically conductive material as the plurality of signal lines TL. However, the embodiments of the present disclosure are not limited thereto. For example, the first electrode CE1 can be made of an electrically conductive material such as titanium (Ti), aluminum (Al), copper (Cu), molybdenum (Mo), nickel (Ni), chromium (Cr), indium tin oxide (ITO), indium zinc oxide (IZO), or indium gallium zinc oxide (IGZO). However, the embodiments of the present disclosure are not limited thereto. In another example, the first electrode CE1 can have a multilayer structure made of an electrically conductive material. For example, the plurality of first electrodes CE1 can each have a multilayer structure made of titanium (Ti), aluminum (Al), titanium (Ti), and indium tin oxide (ITO). However, the embodiments of the present disclosure are not limited thereto.

The micro-LED ED can be disposed in each of the plurality of subpixels. The plurality of micro-LEDs ED can be any one of a light-emitting diode (LED) or a micro-light-emitting diode (micro-LED). However, the embodiments of the present disclosure are not limited thereto. The plurality of micro-LEDs ED can be disposed on the bank BNK and the first electrode CE1. The plurality of micro-LEDs ED can be disposed on the first electrode CE1 and electrically connected to the first electrode CE1. Therefore, the micro-LED ED can emit light by receiving the anode voltage from the pixel drive circuit PD through the signal line TL and the first electrode CE1.

The plurality of micro-LEDs ED can include first micro-LEDs 130, second micro-LEDs 140, and third micro-LEDs 150. The first micro-LED 130 can be disposed in the first subpixel SP1. The second micro-LED 140 can be disposed in the second subpixel SP2. The third micro-LED 150 can be disposed in the third subpixel SP3. For example, any one of the first micro-LED 130, the second micro-LED 140, and the third micro-LED 150 can be a red micro-LED, another micro-LED can be a green micro-LED, the other micro-LED can be a blue micro-LED. However, the embodiments of the present disclosure are not limited thereto. Therefore, light beams with various colors including the white color can be implemented by combining red light, green light, and blue light emitted from the plurality of micro-LEDs ED. The types of micro-LEDs ED are illustrative. However, the embodiments of the present disclosure are not limited thereto.

The first micro-LEDs 130 can include a 1-1-th micro-LED 130a disposed in the 1-1-th subpixel SP1a, and a 1-2-th micro-LED 130b disposed in the 1-2-th subpixel SP1b. The second micro-LEDs 140 can include a 2-1-th micro-LED 140a disposed in the 2-1-th subpixel SP2a, and a 2-2-th micro-LED 140b disposed in the 2-2-th subpixel SP2b. The third micro-LEDs 150 can include a 3-1-th micro-LED 150a disposed in the 3-1-th subpixel SP3a, and a 3-2-th micro-LED 150b disposed in the 3-2-th subpixel SP3b.

With reference to FIGS. 5, 6, and 7 together, the second electrode CE2 can be disposed in each of the plurality of subpixels. The second electrode CE2 can be disposed on the micro-LED ED. The second electrodes CE2 can be electrically connected to the pixel drive circuit PD through a plurality of contact electrodes CCE.

For example, the second electrode CE2 can be electrically connected to a cathode electrode 135 (see for example FIG. 10) of the micro-LED ED and transmit a cathode voltage from the pixel drive circuit PD to the micro-LED ED. The same cathode voltage can be applied to the second electrodes CE2 of the plurality of subpixels. For example, the same voltage can be applied to the second electrode CE2 and the cathode electrode 135 of the micro-LED ED in each of the plurality of subpixels. Therefore, the second electrode CE2 can be a common electrode. However, the embodiments of the present disclosure are not limited thereto.

At least some of the plurality of subpixels can share the second electrode CE2. At least some of the second electrodes CE2 of the plurality of subpixels can be electrically connected to one another. Because the same voltage is applied to the second electrodes CE2, at least some of the subpixels can use and share the second electrode CE2. For example, the second electrodes CE2 of at least some pixels PX of the plurality of pixels PX disposed in the same row can be connected to each other. For example, one second electrode CE2 can be disposed in each of the plurality of pixels PX. One second electrode CE2 can be disposed for each of n subpixels.

For example, some of the second electrodes CE2 of the plurality of subpixels can be disposed to be spaced apart or separated from one another. For example, the second electrodes CE2 connected to the pixels PX disposed in an n-th row and the second electrodes CE2 connected to the pixels PX disposed in an (n+1)th row can be disposed to be spaced apart or separated from one another. For example, the plurality of second electrodes CE2 can be disposed to be spaced apart from one another with the plurality of communication lines NL interposed therebetween and extending in the row direction. Therefore, the number of subpixels can be larger than the number of second electrodes CE2. In another example, all the second electrodes CE2 in the plurality of subpixels can be connected to one another, and only one second electrode CE2 can be disposed on the substrate 110. However, the embodiments of the present disclosure are not limited thereto.

The plurality of second electrodes CE2 can be made of a transparent electrically conductive material. However, the embodiments of the present disclosure are not limited thereto. The plurality of second electrodes CE2 can be made of a transparent electrically conductive material, and the light emitted from the micro-LED ED can be directed toward an upper side of the second electrode CE2. For example, the second electrode CE2 can be made of a transparent electrically conductive material such as indium tin oxide (ITO), indium zinc oxide (IZO), or indium gallium zinc oxide (IGZO). However, the embodiments of the present disclosure are not limited thereto.

The plurality of contact electrodes CCE can be disposed on the substrate 110. For example, the plurality of contact electrodes CCE can be disposed to be spaced apart from the plurality of banks BNK and the plurality of signal lines TL. The plurality of second electrodes CE2 can each overlap at least one contact electrode CCE. For example, one second electrode CE2 can overlap the plurality of contact electrodes CCE.

For example, the plurality of contact electrodes CCE can be electrically connected to the plurality of second electrodes CE2. The plurality of contact electrodes CCE can be disposed between the substrate 110 and the plurality of second electrodes CE2 and transmit the cathode voltage from the pixel drive circuit PD to the second electrode CE2. For example, the plurality of contact electrodes CCE can be electrically connected to the pixel drive circuit PD through a first connection line 121 and receive the cathode voltage from the pixel drive circuit PD.

For example, in case that micro-LEDs are used as the micro-LEDs ED, the display apparatus 1000 can be manufactured by forming the plurality of micro-LEDs on a wafer and transferring the micro-LEDs to the substrate 110 of the display apparatus 1000. Various types of defects can occur during the process of transferring the plurality of micro-LEDs ED having fine sizes to the substrate 110. For example, a non-transfer defect, which is caused when the micro-LEDs ED are not transferred, can occur in some of the subpixels, and a defect, in which the micro-LEDs ED are transferred while deviating from exact positions, can occur because of alignment errors in some of the subpixels. In addition, the transferred micro-LED ED can be defective even though the transfer process is normally performed. Therefore, the plurality of micro-LEDs ED of the same type can be transferred to one subpixel in consideration of defects occurring during the process of transferring the plurality of micro-LEDs ED. A lighting inspection can be performed on the plurality of micro-LEDs ED, and only one micro-LED ED, which is finally determined as being normal, can be used.

For example, both the 1-1-th micro-LED 130a and the 1-2-th micro-LED 130b are transferred to one pixel PX, and whether the 1-1-th micro-LED 130a and the 1-2-th micro-LED 130b are defective can be inspected. If both the 1-1-th micro-LED 130a and the 1-2-th micro-LED 130b are determined as being normal, only the 1-1-th micro-LED 130a can be used, and the 1-2-th micro-LED 130b may not be used. In another example, in case that only the 1-2-th micro-LED 130b between the 1-1-th micro-LED 130a and the 1-2-th micro-LED 130b is determined as being normal, the 1-1-th micro-LED 130a may not be used, and only the 1-2-th micro-LED 130b can be used. Therefore, only one micro-LED ED can be finally used even though the plurality of micro-LEDs ED of the same type are transferred to one pixel PX.

Therefore, any one of the pair of micro-LEDs ED can be a main (main or primary) micro-LED ED, and the other of the pair of micro-LEDs ED can be a redundancy micro-LED ED. The redundancy micro-LED ED can be an extra micro-LED ED transferred to prepare for a defect of the main micro-LED ED. When the main micro-LED ED is defective, the redundancy micro-LED ED can be used instead of the main micro-LED ED. Therefore, both the main micro-LED ED and the redundancy micro-LED ED are transferred to one pixel PX, which can minimize a deterioration in display quality caused by defects of the main micro-LED ED and the redundancy micro-LED ED.

For example, the 1-1-th micro-LED 130a, the 2-1-th micro-LED 140a, and the 3-1-th micro-LED 150a transferred to one pixel PX can be used as the main micro-LEDs ED, and the 1-2-th micro-LED 130b, the 2-2-th micro-LED 140b, and the 3-2-th micro-LED 150b can be used as the redundancy micro-LEDs ED.

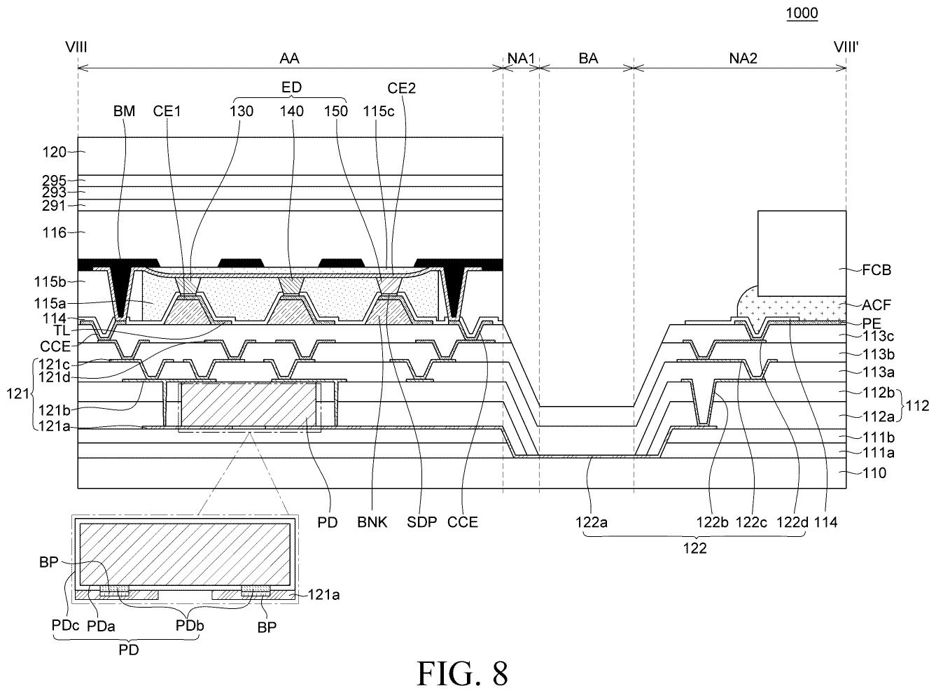

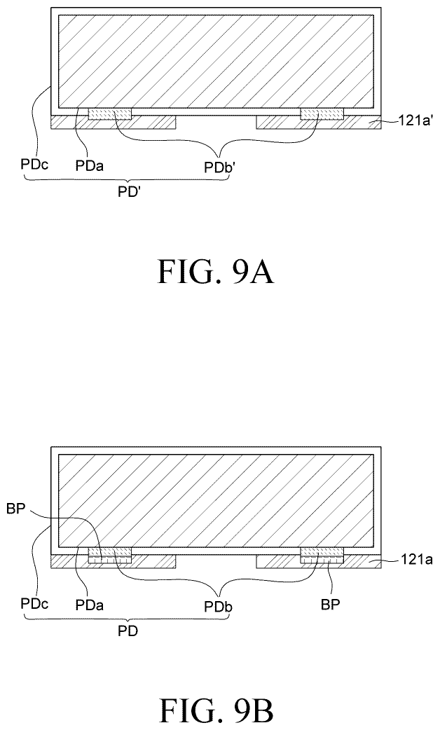

FIG. 8 is a cross-sectional view taken along line VIII-VIII′ in FIG. 3. FIGS. 9A and 9B are enlarged views for explaining a process of joining the pixel drive circuit and a 1-1-th connection line of the display apparatus according to the embodiment of the present disclosure. FIG. 10 is a cross-sectional view of the display apparatus according to the embodiment of the present disclosure. For example, FIG. 8 is a cross-sectional view of the display area AA, the first non-display area NA1, the bending area BA, and the second non-display area NA2. FIGS. 9A and 9B are views for explaining a principle of forming a bonding pattern, in which FIG. 9A is a view illustrating a state before diffusion bonding, and FIG. 9B is a view illustrating a state after diffusion bonding. FIG. 10 is an enlarged cross-sectional view of the first subpixel. Meanwhile, for the convenience of illustration, FIG. 3 illustrates that the cutting line VIII-VIII′, the drive line VL, and the link line LL do not overlap one another. However, the cutting line VIII-VIII′ in FIG. 3 indicates the same position as the adjacent drive line VL and the adjacent link line LL.

With reference to FIG. 8, a first buffer layer 111a and a second buffer layer 111b can be disposed in the remaining area of the substrate 110, except for the bending area BA.

The first buffer layer 111a and the second buffer layer 111b can be disposed in the display area AA, the first non-display area NA1, and the second non-display area NA2. The first buffer layer 111a and the second buffer layer 111b can reduce the permeation of moisture or impurities through the substrate 110. The first buffer layer 111a and the second buffer layer 111b can be made of an inorganic insulating material. For example, the first buffer layer 111a and the second buffer layer 111b can each be configured as a single layer or multilayer made of silicon oxide (SiOx) or silicon nitride (SiNx). However, the embodiments of the present disclosure are not limited thereto.

For example, the first buffer layer 111a and the second buffer layer 111b disposed in the bending area BA can be partially removed. A top surface of the substrate 110 positioned in the bending area BA can be exposed from the first buffer layer 111a and the second buffer layer 111b. The first buffer layer 111a and the second buffer layer 111b, which are made of an inorganic insulating material, are removed from the bending area BA, which can minimize the occurrence of a crack in the first buffer layer 111a and the second buffer layer 111b that can be caused when the bending area BA is bent.

According to the present disclosure, a plurality of first connection lines 121 can be disposed on the second buffer layer 111b in the display area AA. The plurality of first connection lines 121 can be lines configured to electrically connect the pixel drive circuit PD to other constituent elements. For example, the pixel drive circuit PD can be electrically connected to the plurality of signal lines TL, the plurality of contact electrodes CCE, and the like through the plurality of first connection lines 121. For example, the plurality of first connection lines 121 can include 1-1-th connection lines 121a, 1-2-th connection lines 121b, 1-3-th connection lines 121c, and 1-4-th connection lines 121d. However, the embodiments of the present disclosure are not limited thereto.

For example, the plurality of 1-1-th connection lines 121a can be disposed on the second buffer layer 111b. The plurality of 1-1-th connection lines 121a can be electrically connected to the pixel drive circuit PD. The plurality of 1-1-th connection lines 121a can transmit a voltage, which is outputted from the pixel drive circuit PD, to the first electrode CE1 or the second electrode CE2. Meanwhile, the plurality of 1-1-th connection lines 121a can be utilized as alignment keys for aligning the position of the pixel drive circuit PD. However, the present disclosure is not limited thereto.

The plurality of 1-1-th connection lines 121a can include grooves. The grooves of the plurality of 1-1-th connection lines 121a are positions at which a plurality of circuit pads PDb of the pixel drive circuit PD are mounted.

The plurality of 1-1-th connection lines 121a and the plurality of circuit pads PDb are coupled and electrically connected to one another in the grooves of the plurality of 1-1-th connection lines 121a and simultaneously fix the pixel drive circuit PD. For example, the plurality of 1-1-th connection lines 121a and the plurality of circuit pads PDb can be electrically connected by diffusion bonding. For example, the plurality of 1-1-th connection lines 121a and the plurality of circuit pads PDb can be connected by applying predetermined heat and pressure. However, the present disclosure is not limited thereto.

The pixel drive circuit PD can be disposed on the plurality of 1-1-th connection lines 121a in the display area AA. The pixel drive circuit PD can include a body PDa, the plurality of circuit pads PDb, and a passivation film PDc.

The body PDa of the pixel drive circuit PD can be configured to mount various types of components and can be a semiconductor substrate or the like on which various types of components are disposed. However, the present disclosure is not limited thereto.

The plurality of circuit pads PDb can be disposed on a bottom surface of the body PDa of the pixel drive circuit PD and spaced apart from one another. The plurality of circuit pads PDb can be electrically connected to the 1-1-th connection line 121a through a bonding pattern BP and transmit various signals. For example, the plurality of circuit pads PDb can protrude further than the passivation film PDc and be respectively disposed in the grooves of the 1-1-th connection lines 121a. However, the present disclosure is not limited thereto. The plurality of circuit pads PDb can be made of an electrically conductive material, e.g., a material containing titanium (Ti). However, the present disclosure is not limited thereto.

The passivation film PDc of the pixel drive circuit PD can be disposed to surround the body PDa and the plurality of circuit pads PDb. The passivation film PDc can protect the body PDa and the plurality of circuit pads PDb from the permeation of moisture or impurities. The passivation film PDc can be made of an inorganic insulating material, e.g., silicon oxide (SiOx) or silicon nitride (SiNx). However, the present disclosure is not limited thereto.

In case that the pixel drive circuit PD is implemented as an operation driver, the operation driver can be electrically connected to the plurality of 1-1-th connection lines 121a by diffusion bonding while being mounted on the plurality of 1-1-th connection lines 121a by a transfer process. However, the embodiments of the present disclosure are not limited thereto.

With reference to FIGS. 8 to 9B together, the bonding pattern BP can be disposed between the plurality of 1-1-th connection lines 121a and the pixel drive circuit PD. Specifically, the bonding pattern BP can be disposed between the plurality of 1-1-th connection lines 121a and the plurality of circuit pads PDb of the pixel drive circuit PD in the grooves of the plurality of 1-1-th connection lines 121a. The bonding pattern BP can electrically connect the plurality of 1-1-th connection lines 121a and the plurality of circuit pads PDb of the pixel drive circuit PD.

For example, the bonding pattern BP can be formed by diffusion bonding between the 1-1-th connection line 121a and the circuit pad PDb. That is, the bonding pattern BP can be formed between the 1-1-th connection line 121a and the circuit pad PDb as a material, which constitutes the 1-1-th connection line 121a, and a material, which constitutes the circuit pad PDb, are diffused toward each other. However, the present disclosure is not limited thereto.

For example, with reference to FIG. 9A, a material, which constitutes an initial 1-1-th connection line 121a′, can be diffused toward an initial circuit pad PDb′ from a portion where a groove of the initial 1-1-th connection line 121a′, which adjoins the initial circuit pad PDb′, is disposed. Therefore, a thickness of the portion where the groove of the initial 1-1-th connection line 121a′ is disposed can be decreased. That is, a depth of the groove of the initial 1-1-th connection line 121a′ can be further increased. However, the present disclosure is not limited thereto.

Likewise, the material, which constitutes the initial circuit pad PDb′, moves toward the initial 1-1-th connection line 121a′ from a portion where a portion of the initial circuit pad PDb′, which adjoins the initial 1-1-th connection line 121a′, protrudes, such that a thickness of the protruding portion of the initial circuit pad PDb′ can be decreased by a diffusion bonding process. However, the present disclosure is not limited thereto.

That is, with reference to FIGS. 9A and 9B, the bonding pattern BP can be formed between the 1-1-th connection line 121a and the circuit pad PDb by the thicknesses of the initial 1-1-th connection line 121a′ and the circuit pad PDb′ that are decreased by the diffusion bonding process. Therefore, the bonding pattern BP can be disposed between the 1-1-th connection line 121a and the circuit pad PDb in the groove of the 1-1-th connection line 121a and simultaneously adjoin the 1-1-th connection line 121a and the circuit pad PDb. Therefore, the bonding pattern BP can simultaneously fix and electrically connect the 1-1-th connection line 121a and the circuit pad PDb.

Therefore, after the diffusion bonding, the 1-1-th connection line 121a and the circuit pad PDb can be disposed to be spaced apart from each other based on the bonding pattern BP. However, the present disclosure is not limited thereto.

Meanwhile, a thickness of the bonding pattern BP can be determined depending on the thicknesses of the initial 1-1-th connection line 121a′ and the initial circuit pad PDb′. However, the present disclosure is not limited thereto.

For example, the bonding pattern BP can be made of an intermetallic compound. For example, the bonding pattern BP can be made of an intermetallic compound of a material that constitutes the plurality of 1-1-th connection lines 121a and a material that constitutes the plurality of circuit pads PDb of the pixel drive circuit PD. For example, the bonding pattern BP can be made of titanium aluminide (TiAl₃) in case that the 1-1-th connection line 121a is made of aluminum (Al) and the circuit pad PDb is made of titanium (Ti). However, the present disclosure is not limited thereto.

A protective layer 112 can be disposed on the plurality of 1-1-th connection lines 121a and the pixel drive circuit PD. The protective layer 112 can include the first protective layer 112a and the second protective layer 112b. However, the present disclosure is not limited thereto. The protective layer 112 can be configured as a single layer. The first protective layer 112a and the second protective layer 112b can be disposed to surround a side surface of the pixel drive circuit PD. However, the embodiments of the present disclosure are not limited thereto. For example, the second protective layer 112b can be disposed to cover at least a part of a top surface of the pixel drive circuit PD. For example, at least one of the first protective layer 112a and the second protective layer 112b disposed on the bending area BA can be excluded. For example, the first protective layer 112a can be entirely disposed in the display area AA and the non-display area NA, and the second protective layer 112b can be partially disposed in the display area AA, the first non-display area NA1, and the second non-display area NA2. For example, a part of the second protective layer 112b disposed in the bending area BA can be removed. However, the embodiments of the present disclosure are not limited thereto. The first protective layer 112a and the second protective layer 112b disposed in the bending area BA can be partially removed.

The first protective layer 112a and the second protective layer 112b can each be made of an organic insulating material. However, the embodiments of the present disclosure are not limited thereto. For example, the first protective layer 112a and the second protective layer 112b can each be made of photoresist, polyimide (PI), or a photo acrylic material. However, the embodiments of the present disclosure are not limited thereto. For example, the first protective layer 112a and the second protective layer 112b can each be an overcoating layer or an insulation layer. However, the embodiments of the present disclosure are not limited thereto.

The plurality of 1-2-th connection lines 121b can be disposed on the second protective layer 112b. The plurality of 1-2-th connection lines 121b can be connected indirectly or directly to the pixel drive circuit PD. For example, the 1-2-th connection line 121b can be electrically connected to the 1-1-th connection line 121a through a contact hole of the second protective layer 112b. However, the embodiments of the present disclosure are not limited thereto. The voltage outputted from the pixel drive circuit PD can be transmitted to the first electrode CE1 or the second electrode CE2 through a connection line different from the plurality of 1-2-th connection lines 121b.

A first insulation layer 113a can be disposed on the plurality of 1-2-th connection lines 121b. The first insulation layer 113a can be entirely disposed in the display area AA and the non-display area NA. However, the embodiments of the present disclosure are not limited thereto. The first insulation layer 113a can be made of an organic insulating material. However, the embodiments of the present disclosure are not limited thereto. For example, the first insulation layer 113a can be made of photoresist, polyimide (PI), or a photo acrylic material. However, the embodiments of the present disclosure are not limited thereto.

The plurality of 1-3-th connection lines 121c can be disposed on the first insulation layer 113a. The plurality of 1-3-th connection lines 121c can be electrically connected to the plurality of 1-2-th connection lines 121b. For example, the 1-3-th connection line 121c can be electrically connected to the 1-2-th connection line 121b through a contact hole of the first insulation layer 113a.

A second insulation layer 113b can be disposed on the plurality of 1-3-th connection lines 121c. As illustrated in figure, the second insulation layer 113b is disposed in a plurality of areas including the bending area BA. However, the embodiments of the present disclosure are not limited thereto. The second insulation layer 113b can be disposed in the remaining areas, except for the bending area BA. The second insulation layer 113b can be disposed in the display area AA, the first non-display area NA1, and the second non-display area NA2. However, the embodiments of the present disclosure are not limited thereto. For example, a part of the second insulation layer 113b disposed in the bending area BA can be removed. The second insulation layer 113b can be made of an organic insulating material. However, the embodiments of the present disclosure are not limited thereto. For example, the second insulation layer 113b can be made of photoresist, polyimide (PI), or a photo acrylic material. However, the embodiments of the present disclosure are not limited thereto.

The plurality of 1-4-th connection lines 121d can be disposed on the second insulation layer 113b. The plurality of 1-4-th connection lines 121d can be electrically connected to the plurality of 1-3-th connection lines 121c. For example, the 1-4-th connection line 121d can be electrically connected to the 1-3-th connection line 121c through the contact hole of the second insulation layer 113b.

According to the present disclosure, a plurality of second connection lines 122 can be disposed on the second buffer layer 111b in the non-display area NA. The plurality of second connection lines 122 can be lines configured to transmit the signals, which are transmitted to the pad part PAD from the flexible circuit board (or flexible film) FCB and the printed circuit board 160 (see FIG. 1), to the pixel drive circuit PD in the display area AA. For example, the plurality of second connection lines 122 can be electrically connected to the plurality of pad electrodes PE and receive the signals from the flexible circuit board (or flexible film) FCB and the printed circuit board 160. Further, the plurality of second connection lines 122 can transmit signals from the flexible circuit board FCB and the printed circuit board 160 directly to the pixel drive circuit PD or transmit signals to the pixel drive circuit PD through the first connection line 121. The pixel drive circuit PD can output cathode voltages to the plurality of contact electrodes CCE and the plurality of subpixels on the basis of the signals applied from the second connection line 122.

For example, the plurality of second connection lines 122 can extend from the pad part PAD toward the display area AA and transmit signals to the pixel drive circuit PD in the display area AA. In this case, the plurality of second connection lines 122 can serve as the link lines LL. The plurality of second connection lines 122 can include 2-1-th connection lines 122a, 2-2-th connection lines 122b, 2-3-th connection lines 122c, and 2-4-th connection lines 122d.

The plurality of 2-1-th connection lines 122a can be disposed on the second buffer layer 111b. The plurality of 2-1-th connection lines 122a can extend from the second non-display area NA2 to the bending area BA and the first non-display area NA1. Therefore, the 2-1-th connection line 122a can adjoin (for example, partially adjoin) the first buffer layer 111a and the second buffer layer 111b in the display area AA, the first non-display area NA1, and the second non-display area NA2 and adjoin the substrate 110 in the bending area BA. However, the present disclosure is not limited thereto. The plurality of 2-1-th connection lines 122a can transmit the signals, which are transmitted to the pad part PAD from the flexible circuit board (or flexible film) FCB and the printed circuit board 160, to the pixel drive circuit PD in the display area AA. For example, the 2-1-th connection line 122a can extend from the second non-display area NA2 to the first non-display area NA1 and be electrically connected to any one of the 1-1-th connection line 121a, the 1-2-th connection line 121b, the 1-3-th connection line 121c, and the 1-4-th connection line 121d of the plurality of first connection lines 121. For example, the 2-1-th connection line 122a can be connected directly to the 1-1-th connection line 121a disposed on the same layer, or the 2-1-th connection line 122a can be connected to the 1-2-th connection line 121b, which is disposed on another layer, through a contact hole of the protective layer 112. However, the present disclosure is not limited thereto.

The plurality of 2-2-th connection lines 122b can be disposed on the second protective layer 112b. The plurality of 2-2-th connection lines 122b can be disposed in the second non-display area NA2. The 2-2-th connection line 122b can be electrically connected to the 2-1-th connection line 122a through the contact hole of the protective layer 112. Therefore, the signals from the flexible circuit board (or flexible film) FCB and the printed circuit board 160 can be transmitted to the 2-1-th connection line 122a through the 2-2-th connection line 122b.

The 2-3-th connection line 122c can be disposed on the first insulation layer 113a. The 2-3-th connection line 122c can be disposed in the second non-display area NA2. The 2-3-th connection line 122c can be electrically connected to the 2-2-th connection line 122b through the contact hole of the first insulation layer 113a. Therefore, the signals from the flexible circuit board (or flexible film) FCB and the printed circuit board 160 can be transmitted to the 2-1-th connection line 122a through the 2-3-th connection line 122c and the 2-2-th connection line 122b.

The 2-4-th connection line 122d can be disposed on the second insulation layer 113b. The 2-4-th connection line 122d can be disposed in the second non-display area NA2. The 2-4-th connection line 122d can be electrically connected to the 2-3-th connection line 122c through the contact hole of the second insulation layer 113b. Therefore, the signals from the flexible circuit board (or flexible film) FCB and the printed circuit board 160 can be transmitted to the 2-1-th connection line 122a through the 2-4-th connection line 122d, the 2-3-th connection line 122c, and the 2-2-th connection line 122b.

The plurality of first connection lines 121 and the plurality of second connection lines 122 can be made of any one of electrically conductive materials with excellent flexibility or various electrically conductive materials used for the display area AA. For example, the second connection line 122 partially disposed in the bending area BA can be made of an electrically conductive material, such as gold (Au), silver (Ag), or aluminum (Al), that is excellent in flexibility. However, the embodiments of the present disclosure are not limited thereto. In another example, the plurality of first connection lines 121 and the plurality of second connection lines 122 can be made of molybdenum (Mo), chromium (Cr), titanium (Ti), nickel (Ni), neodymium (Nd), copper (Cu), and an alloy of silver (Ag) and magnesium (Mg), or an alloy thereof. However, the embodiments of the present disclosure are not limited thereto.

A third insulation layer 113c can be disposed on the plurality of first connection lines 121 and the plurality of second connection lines 122. The third insulation layer 113c can be disposed in the remaining area, except for the bending area BA. However, the embodiments of the present disclosure are not limited thereto. The third insulation layer 113c can be disposed in the display area AA, the first non-display area NA1, and the second non-display area NA2. A part of the third insulation layer 113c disposed in the bending area BA can be removed. The third insulation layer 113c can be made of an organic insulating material. However, the embodiments of the present disclosure are not limited thereto. For example, the third insulation layer 113c can be made of photoresist, polyimide (PI), or a photo acrylic material. However, the embodiments of the present disclosure are not limited thereto.

The plurality of banks BNK can be disposed on the third insulation layer 113c in the display area AA. The plurality of banks BNK can be disposed to overlap the plurality of subpixels. One or more micro-LEDs ED of the same type can be disposed above the plurality of banks BNK.

The plurality of signal lines TL can be disposed on the third insulation layer 113c in the display area AA. The plurality of signal lines TL can be disposed in areas between the plurality of banks BNK. For example, the plurality of signal lines TL can be disposed adjacent to any one of the plurality of banks BNK.

The plurality of contact electrodes CCE can be disposed on the third insulation layer 113c in the display area AA. The plurality of contact electrodes CCE can supply the cathode voltage from the pixel drive circuit PD to the second electrode CE2.

The first electrode CE1 can be disposed on the bank BNK. For example, the first electrode CE1 can be disposed to extend from the adjacent signal line TL to the upper side of the bank BNK. The first electrode CE1 can be disposed on the top surface of the bank BNK and the side surface of the bank BNK. For example, the first electrode CE1 can be disposed to extend from the signal line TL on the top surface of the third insulation layer 113c to the side surface of the bank BNK and the top surface of the bank BNK.

With reference to FIG. 10, the first electrode CE1 can include a plurality of conductive layers. For example, the first electrode CE1 can include a first conductive layer CE1a, a second conductive layer CE1b, a third conductive layer CE1c, and a fourth conductive layer CE1d. However, the embodiments of the present disclosure are not limited thereto.

The first conductive layer CE1a can be disposed on the bank BNK. The second conductive layer CE1b can be disposed on the first conductive layer CE1a. The third conductive layer CE1c can be disposed on the second conductive layer CE1b. The fourth conductive layer CE1d can be disposed on the third conductive layer CE1c. For example, the first conductive layer CE1a, the second conductive layer CE1b, the third conductive layer CE1c, and the fourth conductive layer CE1d can each be made of titanium (Ti), molybdenum (Mo), aluminum (Al), or indium tin oxide (ITO). However, the embodiments of the present disclosure are not limited thereto.

According to the present disclosure, among the plurality of conductive layers constituting the first electrode CE1, some conductive layers with high reflection efficiency can include alignment keys for aligning the micro-LEDs ED, and/or reflective plates. For example, among the plurality of conductive layers of the first electrode CE1, the second conductive layer CE1b can include a reflective material. For example, the second conductive layer CE1b can include aluminum (Al). However, the embodiments of the present disclosure are not limited thereto. Therefore, the second conductive layer CE1b can be configured as a reflective plate. In addition, with the high reflection efficiency of the second conductive layer CE1b, the second conductive layer CE1b can be easily identified during the manufacturing process. Therefore, the position or transfer position of the micro-LED ED can be aligned with respect to the second conductive layer CE1b.

For example, in order to configure the second conductive layer CE1b as a reflective plate, the third conductive layer CE1c and the fourth conductive layer CE1d, which cover the second conductive layer CE1b, can be partially removed or etched. For example, the third conductive layer CE1c and the fourth conductive layer CE1d disposed on the bank BNK can be partially removed or etched, such that a top surface of the second conductive layer CE1b can be exposed. For example, central portions and rim portions (or edge portions) of the third conductive layer CE1c and the fourth conductive layer CE1d where solder patterns SDP are disposed can be maintained, and the remaining portions excluding the above-mentioned portions can be removed. For example, the rim portion (or edge portion) of the third conductive layer CE1c made of titanium (Ti) and the rim portion (or edge portion) of the fourth conductive layer CE1d made of indium tin oxide (ITO) may not be etched. Therefore, it is possible to inhibit the other conductive layers of the first electrode CE1 from being corroded by a tetramethyl ammonium hydroxide (TMAH) solution used for a mask process for the first electrode CE1.

According to the present disclosure, the first conductive layer CE1a and the third conductive layer CE1c can include titanium (Ti) or molybdenum (Mo). The second conductive layer CE1b can include aluminum (Al). The fourth conductive layer CE1d can include a transparent conductive oxide layer made of indium tin oxide (ITO) or indium zinc oxide (IZO) having high bondability to the solder pattern SDP and having corrosion resistance and acid resistance. However, the embodiments of the present disclosure are not limited thereto.

The first conductive layer CE1a, the second conductive layer CE1b, the third conductive layer CE1c, and the fourth conductive layer CE1d can be sequentially deposited and then patterned by a photolithography process and an etching process. However, the embodiments of the present disclosure are not limited thereto.

According to the present disclosure, the signal line TL, the contact electrode CCE, and the pad electrode PE disposed on the same layer as the first electrode CE1 can each be configured as a multilayer made of an electrically conductive material. However, the embodiments of the present disclosure are not limited thereto. For example, the signal line TL, the contact electrode CCE, and the pad electrode PE can each be configured as a multilayer made of indium tin oxide (ITO), titanium (Ti), aluminum (Al), and titanium (Ti). However, the embodiments of the present disclosure are not limited thereto.

According to the present disclosure, the solder pattern SDP can be disposed on the first electrode CE1 in each of the plurality of subpixels. The solder pattern SDP can electrically connect the first electrode CE1 and the micro-LED ED by bonding the micro-LED ED to the first electrode CE1. For example, the first electrode CE1 and the anode electrode 134 of the micro-LED ED can be electrically connected by eutectic bonding using the solder pattern SDP. However, the embodiments of the present disclosure are not limited thereto. For example, in case that the solder pattern SDP is made of indium (In) and the anode electrode 134 of the micro-LED ED is made of gold (Au), the solder pattern SDP and the anode electrode 134 can be joined by applying heat and pressure during the process of transferring the micro-LED ED. The micro-LED ED can be joined to the solder pattern SDP and the first electrode CE1 by eutectic bonding without a separate bonding material. For example, the solder pattern SDP can be made of indium (In), tin (Sn), or an alloy thereof. However, the embodiments of the present disclosure are not limited thereto. For example, the solder pattern SDP can be a bonding pad or a joining pad. However, the embodiments of the present disclosure are not limited thereto.

According to the present disclosure, a passivation layer 114 can be disposed on the plurality of signal lines TL, the plurality of first electrodes CE1, the plurality of contact electrodes CCE, and the third insulation layer 113c. For example, the passivation layer 114 can be disposed in the display area AA, the first non-display area NA1, and the second non-display area NA2. A part of the passivation layer 114 disposed in the bending area BA can be removed. A part of the passivation layer 114, which covers the plurality of pad electrodes PE in the second non-display area NA2, can be removed. The passivation layer 114 is disposed to cover the remaining area excluding the areas in which the bending area BA, the plurality of pad electrodes PE, and the solder pattern SDP are disposed, and as a result, it is possible to reduce the permeation of moisture or impurities introduced into the micro-LED ED. For example, the passivation layer 114 can be configured as a single layer or multilayer made of silicon oxide (SiOx) or silicon nitride (SiNx). However, the embodiments of the present disclosure are not limited thereto. For example, the passivation layer 114 can be a protective layer, an insulation layer, or the like. However, the embodiments of the present disclosure are not limited thereto. For example, the passivation layer 114 can include a hole through which the solder pattern SDP is exposed.

In each of the plurality of subpixels, the micro-LED ED can be disposed on the solder pattern SDP. The first micro-LED 130 can be disposed in the first subpixel SP1. The second micro-LED 140 can be disposed in the second subpixel SP2. The third micro-LED 150 can be disposed in the third subpixel SP3.

The micro-LED ED can be formed on a silicon wafer by a method such as metal-organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering. However, the embodiments of the present disclosure are not limited thereto.

With reference to FIG. 10, the first micro-LED 130 can include the anode electrode 134, a first semiconductor layer 131, an active layer 132, a second semiconductor layer 133, the cathode electrode 135, and an encapsulation film 136. However, the embodiments of the present disclosure are not limited thereto. For example, the first micro-LED 130 may not include the encapsulation film 136.

The first semiconductor layer 131 can be disposed on the solder pattern SDP. The second semiconductor layer 133 can be disposed on the first semiconductor layer 131.

For example, one of the first semiconductor layer 131 and the second semiconductor layer 133 can be implemented as a III-V group or II-VI group compound semiconductor and doped with impurities (or dopant). For example, one of the first semiconductor layer 131 and the second semiconductor layer 133 can be a semiconductor layer doped with n-type impurities, and the other of the first semiconductor layer 131 and the second semiconductor layer 133 can be a semiconductor layer doped with p-type impurities. However, the embodiments of the present disclosure are not limited thereto. For example, one of or both the first semiconductor layer 131 and the second semiconductor layer 133 can be layers made by doping a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs) with n-type or p-type impurities. However, the embodiments of the present disclosure are not limited thereto. For example, the n-type impurity can be silicon (Si), germanium (Ge), selenium (Se), carbon (C), tellurium (Te), tin (Sn), or the like. However, the embodiments of the present disclosure are not limited thereto. For example, the p-type impurity can be magnesium (Mg), zinc (Zn), calcium (Ca), strontium (Sr), barium (Ba), beryllium (Be), or the like. However, the embodiments of the present disclosure are not limited thereto.

For example, the first semiconductor layer 131 and the second semiconductor layer 133 can be respectively a nitride semiconductor containing n-type impurities and a nitride semiconductor containing p-type impurities. However, the embodiments of the present disclosure are not limited thereto. For example, the first semiconductor layer 131 can be a nitride semiconductor containing p-type impurities, and the second semiconductor layer 133 can be a nitride semiconductor containing n-type impurities. However, the embodiments of the present disclosure are not limited thereto.

The active layer 132 can be disposed between the first semiconductor layer 131 and the second semiconductor layer 133. The active layer 132 can emit light by receiving positive holes and electrons from the first semiconductor layer 131 and the second semiconductor layer 133. For example, the active layer 132 can have any one of a single well structure, a multi-well structure, a single quantum well structure, a multi-quantum well (MQW) structure, a quantum dot structure, and a quantum line structure. However, the embodiments of the present disclosure are not limited thereto. For example, the active layer 132 can be made of indium gallium nitride (InGaN), gallium nitride (GaN), or the like. However, the embodiments of the present disclosure are not limited thereto.

In another example, the active layer 132 can include a multi-quantum well (MQW) structure having a well layer, and a barrier layer having a higher band gap than the well layer. For example, the active layer 132 can configure an InGaN layer as the well layer and configure an AlGaN layer as the barrier layer. However, the embodiments of the present disclosure are not limited thereto.

The anode electrode 134 can be disposed between the first semiconductor layer 131 and the solder pattern SDP. For example, the anode electrode 134 can electrically connect the first semiconductor layer 131 and the first electrode CE1. The anode voltage outputted from the pixel drive circuit PD can be applied to the first semiconductor layer 131 through the signal line TL, the first electrode CE1, and the anode electrode 134. For example, the anode electrode 134 can be made of an electrically conductive material that can be bonded to the solder pattern SDP by eutectic bonding. However, the embodiments of the present disclosure are not limited thereto. For example, the anode electrode 134 can be made of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), copper (Cu), or an alloy thereof. However, the embodiments of the present disclosure are not limited thereto.

The cathode electrode 135 can be disposed on the second semiconductor layer 133. For example, the cathode electrode 135 can electrically connect the second semiconductor layer 133 and the second electrode CE2. The cathode voltage outputted from the pixel drive circuit PD can be applied to the second semiconductor layer 133 through the contact electrode CCE, the second electrode CE2, and the cathode electrode 135. The cathode electrode 135 can be made of a transparent electrically conductive material so that the light emitted from the micro-LED ED can propagate to the upper side of the micro-LED ED. However, the embodiments of the present disclosure are not limited thereto. For example, the cathode electrode 135 can be made of a material such as indium tin oxide (ITO), indium zinc oxide (IZO), or indium gallium zinc oxide (IGZO). However, the embodiments of the present disclosure are not limited thereto.

The encapsulation film 136 can be at least partially disposed on the first semiconductor layer 131, the active layer 132, the second semiconductor layer 133, the anode electrode 134, and the cathode electrode 135. For example, the encapsulation film 136 can at least partially surround the first semiconductor layer 131, the active layer 132, the second semiconductor layer 133, the anode electrode 134, and the cathode electrode 135.

For example, the encapsulation film 136 can protect the first semiconductor layer 131, the active layer 132, and the second semiconductor layer 133. For example, the encapsulation film 136 can be disposed on a side surface of the first semiconductor layer 131, a side surface of the active layer 132, and a side surface of the second semiconductor layer 133.

For example, the encapsulation film 136 can be disposed on at least a part of the anode electrode 134 and at least a part of the cathode electrode 135, e.g., an edge portion (or edge portion or one side) of the anode electrode 134 and an edge portion (or edge portion or one side) of the cathode electrode 135. At least a part of the anode electrode 134 can be exposed from the encapsulation film 136, such that the anode electrode 134 and the solder pattern SDP can be connected. For example, at least a part of the cathode electrode 135 can be exposed from the encapsulation film 136, such that the cathode electrode 135 and the second electrode CE2 can be connected. For example, the encapsulation film 136 can be made of an insulating material such as silicon nitride (SiNx) or silicon oxide (SiOx). However, the embodiments of the present disclosure are not limited thereto.

In another example, the encapsulation film 136 can have a structure in which a reflective material is dispersed in a resin layer. However, the embodiments of the present disclosure are not limited thereto. For example, the encapsulation film 136 can be manufactured as a reflector having various structures. However, the embodiments of the present disclosure are not limited thereto. The light emitted from the active layer 132 is reflected upward by the encapsulation film 136, which can improve the light extraction efficiency. For example, the encapsulation film 136 can be a reflective layer. However, the embodiments of the present disclosure are not limited thereto.

According to the present disclosure, the micro-LED ED has been described as having a vertical structure. However, the embodiments of the present disclosure are not limited thereto. For example, the micro-LED ED can have a lateral structure or a flip chip structure.

The first micro-LED 130 has been described with reference to FIG. 10. The second micro-LED 140 and the third micro-LED 150 can have substantially the same structure as the first micro-LED 130. For example, the first semiconductor layer 131, the active layer 132, the second semiconductor layer 133, the anode electrode 134, the cathode electrode 135, and the encapsulation film 136 of the first micro-LED 130 can be substantially identical to those of the second micro-LED 140 and the third micro-LED 150.

According to the present disclosure, first optical layers 115a can be disposed to surround the plurality of micro-LEDs ED in the display area AA. For example, the first optical layers 115a can be disposed to cover the plurality of micro-LEDs ED and the bank BNK in the areas of the plurality of subpixels. For example, the first optical layer 115a can cover the bank BNK, a part of the passivation layer 114, and the portions between the plurality of micro-LEDs ED. The first optical layers 115a can be disposed between the plurality of micro-LEDs ED included in one pixel PX and between the plurality of banks BNK or cover the plurality of micro-LEDs ED and the plurality of banks BNK. For example, the first optical layers 115a can extend in the row direction and be disposed to be spaced apart from each other in the column direction. For example, the first optical layer 115a can be disposed between the passivation layer 114 and the second electrode CE2 and surround a side portion (or a side surface) of the micro-LED ED and a side portion (or a side surface) of the bank BNK. However, the embodiments of the present disclosure are not limited thereto. For example, the first optical layer 115a can be a diffusion layer, a sidewall diffusion layer, or the like. However, the embodiments of the present disclosure are not limited thereto.

The first optical layer 115a can include an organic insulating material in which fine particles are dispersed. However, the embodiments of the present disclosure are not limited thereto. For example, the first optical layer 115a can be made of siloxane in which fine metal particles such as titanium dioxide (TiO₂) particles are dispersed. However, the embodiments of the present disclosure are not limited thereto. The light emitted from the plurality of micro-LEDs ED can be scattered by the fine particles dispersed in the first optical layer 115a, and the light can be discharged to the outside of the display apparatus 1000. Therefore, the first optical layer 115a can improve the efficiency in extracting light emitted from the plurality of micro-LEDs ED.

For example, the first optical layer 115a can be respectively disposed in the plurality of pixels PX or disposed together with some of the pixels PX disposed in the same row. However, the embodiments of the present disclosure are not limited thereto. For example, the first optical layer 115a can be disposed in each of the plurality of pixels PX, or the plurality of pixels PX can share one first optical layer 115a. In another example, the plurality of subpixels can each separately include the first optical layer 115a. However, the embodiments of the present disclosure are not limited thereto.

According to the present disclosure, a second optical layer 115b can be disposed on the third insulation layer 113c in the display area AA. For example, the second optical layer 115b can be disposed to surround the first optical layer 115a. For example, the second optical layer 115b can adjoin a side surface of the first optical layer 115a. For example, the second optical layer 115b can be disposed in an area between the plurality of pixels PX. However, the embodiments of the present disclosure are not limited thereto. For example, the second optical layer 115b can be a diffusion layer, a diffusion layer window, a window diffusion layer, or the like. However, the embodiments of the present disclosure are not limited thereto.

The second optical layer 115b can be made of an organic insulating material. However, the embodiments of the present disclosure are not limited thereto. The second optical layer 115b can be made of the same material as the first optical layer 115a. However, the embodiments of the present disclosure are not limited thereto. For example, the first optical layer 115a can include fine particles, and the second optical layer 115b can include no fine particle. For example, the second optical layer 115b can be made of siloxane. However, the embodiments of the present disclosure are not limited thereto.

For example, a thickness of the first optical layer 115a can be smaller than a thickness of the second optical layer 115b. However, the embodiments of the present disclosure are not limited thereto. Therefore, when viewed in a plan view, an area, in which the first optical layer 115a is disposed, can include a concave portion recessed inward from a top surface of the second optical layer 115b.

According to the present disclosure, the second electrode CE2 can be disposed on the first optical layer 115a and the second optical layer 115b. For example, the second electrode CE2 can be electrically connected to the plurality of contact electrodes CCE through the contact hole of the second optical layer 115b. For example, the second electrode CE2 can be disposed on the plurality of micro-LEDs ED. For example, the second electrode CE2 can include a transparent conductive oxide made of indium tin oxide (ITO), indium zinc oxide (IZO), or the like. However, the embodiments of the present disclosure are not limited thereto. For example, the second electrode CE2 can be disposed to be in contact with the cathode electrode 135. For example, the second electrode CE2 can overlap the first optical layer 115a. For example, the second electrode CE2 can cover an outer flat surface of the first optical layer 115a.

The second electrode CE2 can continuously extend in a first direction of the substrate 110. Therefore, the second electrode CE2 can be connected in common to the plurality of pixels PX arranged in the first direction of the substrate 110. For example, the second electrode CE2 can be connected in common to the plurality of pixels PX.

According to the present disclosure, the second electrode CE2 can continuously extend on the first optical layer 115a, the second optical layer 115b, and the micro-LED ED. The area, in which the first optical layer 115a is disposed, can include the concave portion recessed inward from the top surface of the second optical layer 115b. Therefore, because a first portion of the second electrode CE2 disposed on the first optical layer 115a is disposed along the concave portion, the first portion of the second electrode CE2 can be disposed at a position lower than a second portion of the second electrode CE2 disposed on the second optical layer 115b.

A third optical layer 115c can be disposed on the second electrode CE2. The third optical layer 115c can be disposed to overlap the plurality of micro-LEDs ED and the first optical layer 115a. Because the third optical layer 115c is disposed above the second electrode CE2 and the plurality of micro-LEDs ED, it is possible to suppress a Mura that can occur in some of the plurality of micro-LEDs ED. For example, when the plurality of micro-LEDs ED are transferred onto the substrate 110 of the display apparatus 1000, there can occur an area in which intervals between the plurality of micro-LEDs ED are not uniform because of a process deviation or the like. In case that the intervals between the plurality of micro-LEDs ED are not uniform, light-emitting areas of the plurality of micro-LEDs ED can be disposed non-uniformly, and a user can visually recognize a Mura. Therefore, the third optical layer 115c, which is configured to uniformly diffuse light, is provided above the plurality of micro-LEDs ED, which can reduce a situation in which the light emitted from some of the micro-LEDs ED is visually recognized as a Mura. Therefore, the light emitted from the plurality of micro-LEDs ED can be uniformly diffused by the third optical layer 115c and extracted to the outside of the display apparatus 1000, which can improve the luminance uniformity of the display apparatus 1000.

The third optical layer 115c can be made of an organic insulating material in which fine particles are dispersed. However, the embodiments of the present disclosure are not limited thereto. For example, the third optical layer 115c can be made of siloxane in which fine metal particles such as titanium dioxide (TiO₂) particles are dispersed. However, the embodiments of the present disclosure are not limited thereto. For example, the third optical layer 115c can be made of the same material as the first optical layer 115a. However, the embodiments of the present disclosure are not limited thereto. For example, the third optical layer 115c can be a diffusion layer or a top diffusion layer. However, the embodiments of the present disclosure are not limited thereto.

According to the present disclosure, the light emitted from the plurality of micro-LEDs ED can be scattered by the fine particles dispersed in the third optical layer 115c, and the light can be discharged to the outside of the display apparatus 1000. The third optical layer 115c can uniformly mix the light beams emitted from the plurality of micro-LEDs ED, which can further improve the luminance uniformity of the display apparatus 1000. Further, the light extraction efficiency of the display apparatus 1000 can be improved by the light scattered by the plurality of fine particles, such that the display apparatus 1000 can operate with low power consumption.

The black matrix BM can be disposed on the second electrode CE2, the first optical layer 115a, the second optical layer 115b, and the third optical layer 115c in the display area AA. For example, the contact hole of the second optical layer 115b can be filled with the black matrix BM. Because the black matrix BM is configured to cover the display area AA, it is possible to reduce a color mixture and external light reflection of the light emitted from the plurality of subpixels. For example, the black matrix BM is disposed even in the contact hole through which the second electrode CE2 and the contact electrode CCE are connected, which can suppress a leak of light between the plurality of adjacent subpixels.

For example, the black matrix BM can be made of an opaque material. However, the embodiments of the present disclosure are not limited thereto. For example, the black matrix BM can be made of an organic insulating material to which a black pigment or a black dye is added. However, the embodiments of the present disclosure are not limited thereto.

A cover layer 116 can be disposed on the black matrix BM in the display area AA. The cover layer 116 can protect components disposed below the cover layer 116. For example, the cover layer 116 can be made of an organic insulating material. However, the embodiments of the present disclosure are not limited thereto. For example, the cover layer 116 can be made of photoresist, polyimide (PI), or a photo acrylic material. However, the embodiments of the present disclosure are not limited thereto. For example, the cover layer 116 can be an overcoating layer, an insulation layer, or the like. However, the embodiments of the present disclosure are not limited thereto.

The polarizing layer 293 can be disposed on the cover layer 116 by means of a first bonding layer 291. The cover member 120 can be disposed on the polarizing layer 293 by means of a second bonding layer 295. For example, the first bonding layer 291 and the second bonding layer 295 can each include an optically clear adhesive (OCA), an optically clear resin (OCR), a pressure-sensitive adhesive (PSA), or the like. However, the embodiments of the present disclosure are not limited thereto.

According to the present disclosure, the plurality of pad electrodes PE can be disposed on the third insulation layer 113c in the second non-display area NA2. For example, the plurality of pad electrodes PE can be at least partially exposed from the passivation layer 114. For example, the plurality of pad electrodes PE can be electrically connected to the 2-4-th connection line 122d through the contact hole of the third insulation layer 113c.

A bonding layer ACF can be disposed on the plurality of pad electrodes PE. The bonding layer ACF can be a bonding layer made by dispersing conductive balls in an insulating material. However, the embodiments of the present disclosure are not limited thereto. In case that heat or pressure is applied to the bonding layer ACF, the conductive balls are electrically connected in a portion to which heat or pressure is applied, such that the bonding layer ACF can have conductive properties. The bonding layer ACF can be disposed between the plurality of pad electrodes PE and the flexible circuit board (or flexible film) FCB and attach or bond the flexible circuit board (or flexible film) FCB to the plurality of pad electrodes PE. For example, the bonding layer ACF can be an anisotropic conductive film (ACF). However, the embodiments of the present disclosure are not limited thereto.

The flexible circuit board (or flexible film) FCB can be disposed on the bonding layer ACF. The flexible circuit board (or flexible film) FCB can be electrically connected to the plurality of pad electrodes PE through the bonding layer ACF. Therefore, the signals outputted from the flexible circuit board (or flexible film) FCB and the printed circuit board 160 can be transmitted to the pixel drive circuit PD in the display area AA through the plurality of pad electrodes PE, the 2-4-th connection line 122d, the 2-3-th connection line 122c, the 2-2-th connection line 122b, and the 2-1-th connection line 122a.

In the display apparatus, the pixel drive circuit including a micro-driver can be disposed below the micro-LED to operate the micro-LED. In this regard, various constituent elements are required, and processes for forming various constituent elements are required.

For example, a bonding layer can be disposed between the substrate and the pixel drive circuit to fix the pixel drive circuit onto the substrate. In general, because the bonding layer is made of an insulating material, requiring a process of separately disposing alignment keys, which are a made of a metallic material, around the bonding layer in order to align the position of the pixel drive circuit.

In addition, in case that the bonding layer is disposed on the entire substrate, foreign substances can be attached to an area, which excludes an area in which the pixel drive circuit is disposed, during the process. In case that the protective layer or the insulation layer is disposed in the state in which foreign substances are attached, the flatness of the upper portion of the protective layer or the insulation layer can deteriorate. For this reason, there is a problem in that a process of removing foreign substances needs to be additionally performed.

Meanwhile, in case that the passivation film surrounds the circuit pad of the pixel drive circuit, a process of removing the passivation film to expose the circuit pad needs to be additionally performed.

For example, the circuit pad of the pixel drive circuit can be disposed to be directed upward, i.e., directed toward the micro-LED. Therefore, all the plurality of connection lines for connecting the circuit pad and the micro-LED can be disposed on the pixel drive circuit. In general, the protective layer can be disposed to surround the pixel drive circuit in order to planarize upper portions of the area, in which the pixel drive circuit is disposed, and of the peripheral area. For example, the protective layer can be disposed at least by a thickness of the pixel drive circuit.

However, in case that all the plurality of connection lines for connecting the micro-LED and the pixel drive circuit are disposed on the pixel drive circuit as described above, an additional protective layer or insulation layer needs to be disposed on the protective layer in order to insulate the plurality of connection lines from one another. For this reason, the process costs and time are increased, and the number of layered structures is increased, which makes it difficult to implement a thin display apparatus. Furthermore, in case that a plurality of additional protective layers or insulation layers are disposed, there is a problem in that the flatness of the upper portion of the substrate deteriorates.

In the display apparatus 1000 according to the embodiment of the present disclosure, the pixel drive circuit PD is disposed on the 1-1-th connection line 121a and bonded without a separate bonding layer, such that the pixel drive circuit PD and the 1-1-th connection line 121a can be electrically connected, and the pixel drive circuit PD can be fixed. Specifically, the pixel drive circuit PD can be disposed such that the circuit pad PDb is disposed to be directed downward, such that the pixel drive circuit PD can be disposed on the 1-1-th connection line 121a disposed below the pixel drive circuit PD. For example, the circuit pad PDb disposed on the bottom surface of the body PDa of the pixel drive circuit PD can be disposed to protrude further than the passivation film PDc, and the 1-1-th connection line 121a can include the groove. That is, because the circuit pad PDb is disposed in the groove of the 1-1-th connection line 121a, the pixel drive circuit PD can be electrically connected to the 1-1-th connection line 121a while being transferred onto the 1-1-th connection line 121a. That is, the pixel drive circuit PD can be electrically connected to the 1-1-th connection line 121a without the process of removing the passivation film PDc to expose the circuit pad PDb. In this case, the circuit pad PDb and the 1-1-th connection line 121a are structurally coupled, and the circuit pad PDb and the 1-1-th connection line 121a are bonded by diffusion bonding, which can ensure a fixing force made by diffusion bonding.

That is, in the display apparatus 1000 according to the embodiment of the present disclosure, the pixel drive circuit PD can be effectively fixed onto the substrate 110 without a separate bonding layer, and the bonding layer can be excluded, which can reduce the process time and costs. In addition, because the bonding layer is excluded, it is possible to suppress a defect caused when unnecessary foreign substances are attached to the bonding layer. Therefore, because a process of removing foreign substances can also be excluded, which can more effectively reduce the process time and costs.

In addition, in the display apparatus 1000 according to the embodiment of the present disclosure, the layered structure can be further simplified by excluding the bonding layer. Therefore, a thin display apparatus can be implemented, and various constituent elements can be stacked to minimize a problem of a deterioration in flatness of the upper portion of the substrate 110, such that the flatness of the display apparatus 1000 can be ensured.

In addition, because the pixel drive circuit PD is disposed on the 1-1-th connection line 121a made of a metallic material, the 1-1-th connection line 121a can be utilized as an alignment key. Therefore, it is possible to reduce the process time and costs because a process of separately forming an alignment key made of a metallic material to align the position of the pixel drive circuit PD can be excluded.

In addition, in the display apparatus 1000 according to the embodiment of the present disclosure, the 1-1-th connection line 121a and the 1-2-th connection line 121b can be disposed to be spaced apart from each other based on the pixel drive circuit PD and the protective layer 112 that surrounds the pixel drive circuit PD. That is, because the 1-2-th connection line 121b is disposed on the protective layer 112 basically disposed to planarize the pixel drive circuit PD and the peripheral area, a separate additional protective layer or insulation layer does not need to be disposed between the 1-1-th connection line 121a and the 1-2-th connection line 121b. Therefore, it is possible to reduce the process costs and time that can be incurred by an arrangement of an additional protective layer or insulation layer. In addition, the layered structure can be minimized by excluding an additional protective layer or insulation layer, such that a thin display apparatus can be implemented, and the flatness of the upper portion of the substrate 110 can be ensured.

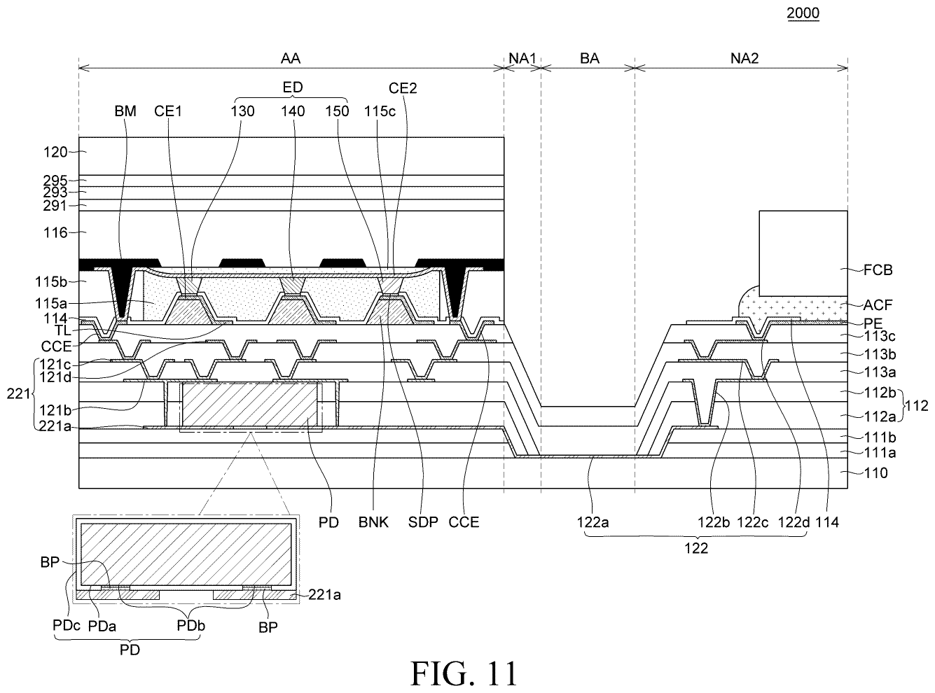

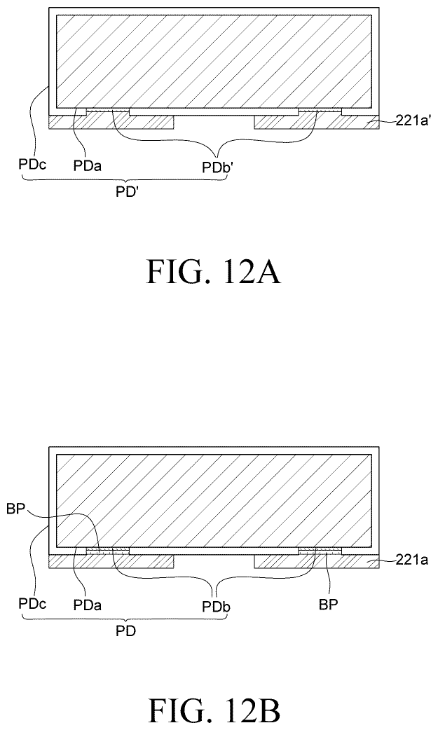

FIG. 11 is a cross-sectional view of a display apparatus according to another embodiment of the present disclosure. FIGS. 12A and 12B are enlarged views for explaining a process of joining a pixel drive circuit and a 1-1-th connection line of the display apparatus according to the another embodiment of the present disclosure. A display apparatus 2000 in FIGS. 11 to 12B is substantially identical in configuration to the display apparatus 1000 in FIGS. 1 to 10, except for the pixel drive circuit PD, the bonding pattern BP, and a 1-1-th connection line 221a. Therefore, repeated descriptions of the identical components will be omitted or may be briefly provided.

With reference to FIG. 11, the plurality of 1-1-th connection lines 221a can include protruding portions. The protruding portions of the plurality of 1-1-th connection lines 221a can be portions coupled to the plurality of circuit pads PDb of the pixel drive circuit PD.

The protruding portions of the plurality of 1-1-th connection lines 221a and the plurality of circuit pads PDb are coupled and electrically connected to one another and simultaneously fix the pixel drive circuit PD. For example, the plurality of 1-1-th connection lines 221a and the plurality of circuit pads PDb can be electrically connected by diffusion bonding. For example, the plurality of 1-1-th connection lines 221a and the plurality of circuit pads PDb can be connected by applying predetermined heat and pressure. However, the present disclosure is not limited thereto.

The plurality of circuit pads PDb can be electrically connected to the 1-1-th connection line 221a through the bonding pattern BP and transmit various signals. For example, the plurality of circuit pads PDb can be disposed inward of the passivation film PDc and respectively coupled to the protruding portions of the 1-1-th connection line 221a. However, the present disclosure is not limited thereto. The plurality of circuit pads PDb can be made of an electrically conductive material, e.g., a material containing titanium (Ti). However, the present disclosure is not limited thereto.

The passivation film PDc of the pixel drive circuit PD can be disposed to surround the body PDa and the plurality of circuit pads PDb. For example, the passivation film PDc can include a groove that exposes the plurality of circuit pads. That is, the protruding portion of the 1-1-th connection line 221a can be disposed in the groove of the passivation film PDc, and the circuit pad PDb, which is exposed by the groove, can be coupled to the 1-1-th connection line 221a. However, the present disclosure is not limited thereto.

With reference to FIGS. 11 to 12B together, the bonding pattern BP can be disposed between the plurality of 1-1-th connection lines 221a and the pixel drive circuit PD. Specifically, the bonding pattern BP can be disposed between the plurality of 1-1-th connection lines 221a and the plurality of circuit pads PDb of the pixel drive circuit PD in the groove of the passivation film PDc. The bonding pattern BP can electrically connect the plurality of 1-1-th connection lines 221a and the plurality of circuit pads PDb of the pixel drive circuit PD.

For example, the bonding pattern BP can be formed by diffusion bonding between the 1-1-th connection line 221a and the circuit pad PDb. That is, the bonding pattern BP can be formed between the 1-1-th connection line 221a and the circuit pad PDb as a material, which constitutes the 1-1-th connection line 221a, and a material, which constitutes the circuit pad PDb, are diffused toward each other. However, the present disclosure is not limited thereto.

For example, with reference to FIG. 12A, a material, which constitutes an initial 1-1-th connection line 221a′, can be diffused toward an initial circuit pad PDb′ from the protruding portion of the initial 1-1-th connection line 221a′ that adjoins the initial circuit pad PDb′. Therefore, a thickness of the protruding portion of the initial 1-1-th connection line 221a′ can be decreased. However, the present disclosure is not limited thereto.

Likewise, the material, which constitutes the initial circuit pad PDb′, moves toward the initial 1-1-th connection line 221a′ from the portion of the initial circuit pad PDb′ that adjoins the initial 1-1-th connection line 221a′, such that a thickness of the initial circuit pad PDb′ can be decreased by the diffusion bonding process. However, the present disclosure is not limited thereto.

That is, with reference to FIGS. 12A and 12B, the bonding pattern BP can be formed between the 1-1-th connection line 221a and the circuit pad PDb by the thicknesses of the initial 1-1-th connection line 221a′ and the circuit pad PDb′ that are decreased by the diffusion bonding process. Therefore, the bonding pattern BP can be disposed between the 1-1-th connection line 221a and the circuit pad PDb in the groove of the passivation film PDc and simultaneously adjoin the 1-1-th connection line 221a and the circuit pad PDb. Therefore, the bonding pattern BP can simultaneously fix and electrically connect the 1-1-th connection line 221a and the circuit pad PDb.

Therefore, after the diffusion bonding, the 1-1-th connection line 221a and the circuit pad PDb can be disposed to be spaced apart from each other based on the bonding pattern BP. However, the present disclosure is not limited thereto.

Meanwhile, a thickness of the bonding pattern BP can be determined depending on the thicknesses of the initial 1-1-th connection line 221a′ and the circuit pad PDb′. However, the present disclosure is not limited thereto.

For example, the bonding pattern BP can be made of an intermetallic compound. For example, the bonding pattern BP can be made of an intermetallic compound of a material that constitutes the plurality of 1-1-th connection lines 221a and a material that constitutes the plurality of circuit pads PDb of the pixel drive circuit PD. For example, the bonding pattern BP can be made of titanium aluminide (TiAl₃) in case that the 1-1-th connection line 221a is made of aluminum (Al) and the circuit pad PDb is made of titanium (Ti). However, the present disclosure is not limited thereto.

In the display apparatus 2000 according to another embodiment of the present disclosure, the pixel drive circuit PD is disposed on the 1-1-th connection line 221a and bonded without a separate bonding layer, such that the pixel drive circuit PD and the 1-1-th connection line 221a can be electrically connected, and the pixel drive circuit PD can be fixed. Specifically, the pixel drive circuit PD can be disposed such that the circuit pad PDb is disposed to be directed downward, such that the pixel drive circuit PD can be disposed on the 1-1-th connection line 221a disposed below the pixel drive circuit PD. For example, the circuit pad PDb disposed on the bottom surface of the body PDa of the pixel drive circuit PD can be disposed inward of the passivation film PDc, and the passivation film PDc can include the groove that exposes the circuit pad PDb. Meanwhile, the 1-1-th connection line 221a can include the protruding portion correspond to the groove of the passivation film PDc. That is, because the protruding portion of the 1-1-th connection line 221a is disposed in the groove of the passivation film PDc that exposes the circuit pad PDb, the pixel drive circuit PD can be electrically connected to the 1-1-th connection line 221a while being transferred onto the 1-1-th connection line 221a. In this case, the circuit pad PDb and the 1-1-th connection line 221a are structurally coupled, and the circuit pad PDb and the 1-1-th connection line 221a are bonded by diffusion bonding, which can ensure a fixing force made by diffusion bonding.

That is, in the display apparatus 2000 according to another embodiment of the present disclosure, the pixel drive circuit PD can be effectively fixed onto the substrate 110 without a separate bonding layer, and the bonding layer can be excluded, which can reduce the process time and costs. In addition, because the bonding layer is excluded, it is possible to suppress a defect caused when unnecessary foreign substances are attached to the bonding layer. Therefore, because a process of removing foreign substances can also be excluded, which can more effectively reduce the process time and costs.

In addition, in the display apparatus 2000 according to another embodiment of the present disclosure, the layered structure can be further simplified by excluding the bonding layer. Therefore, a thin display apparatus can be implemented, and various constituent elements can be stacked to minimize a problem of a deterioration in flatness of the upper portion of the substrate 110, such that the flatness of the display apparatus 2000 can be ensured.

Since the pixel drive circuit PD is disposed on the 1-1-th connection line 221a made of a metallic material, the 1-1-th connection line 221a can be utilized as an alignment key. Therefore, it is possible to reduce the process time and costs because a process of separately forming an alignment key made of a metallic material to align the position of the pixel drive circuit PD can be excluded.

In the display apparatus 2000 according to another embodiment of the present disclosure, the 1-1-th connection line 221a and the 1-2-th connection line 121b can be disposed to be spaced apart from each other based on the pixel drive circuit PD and the protective layer 112 that surrounds the pixel drive circuit PD. That is, because the 1-2-th connection line 121b is disposed on the protective layer 112 basically disposed to planarize the pixel drive circuit PD and the peripheral area, a separate additional protective layer or insulation layer does not need to be disposed between the 1-1-th connection line 221a and the 1-2-th connection line 121b. Therefore, it is possible to reduce the process costs and time that can be incurred by an arrangement of an additional protective layer or insulation layer. In addition, the layered structure can be minimized by excluding an additional protective layer or insulation layer, such that a thin display apparatus can be implemented, and the flatness of the upper portion of the substrate 110 can be ensured.

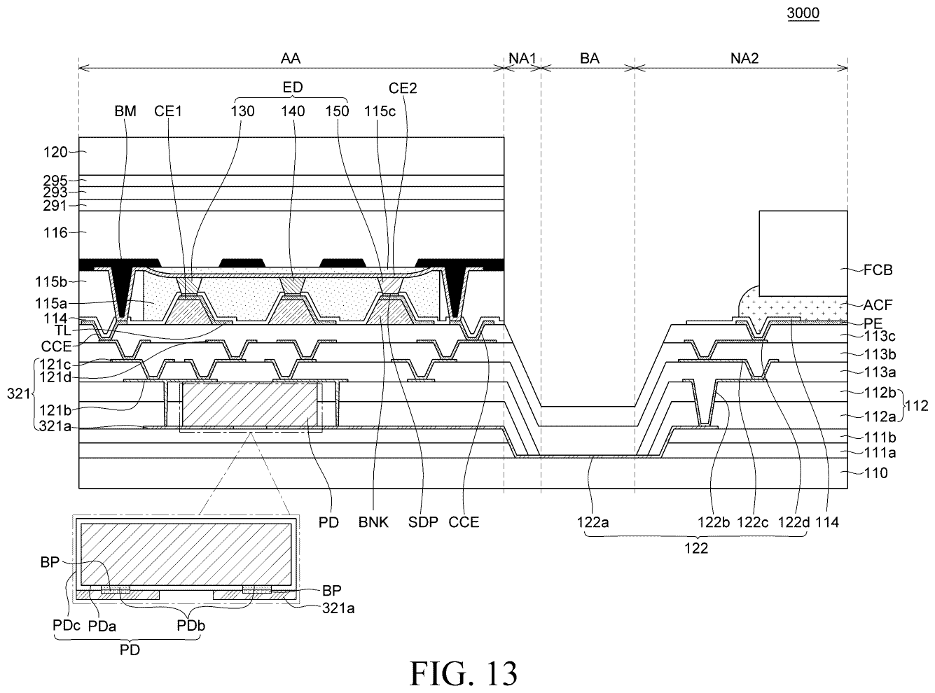

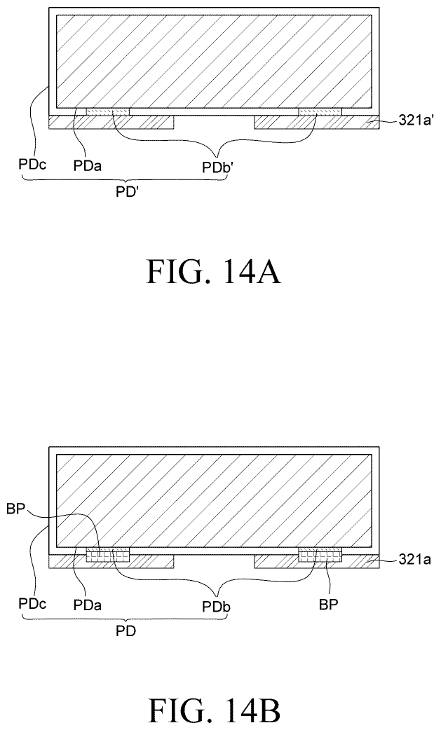

FIG. 13 is a cross-sectional view of a display apparatus according to still another embodiment of the present disclosure. FIGS. 14A and 14B are enlarged views for explaining a process of joining a pixel drive circuit and a 1-1-th connection line of the display apparatus according to still another embodiment of the present disclosure. A display apparatus 3000 in FIGS. 13 to 14B is substantially identical in configuration to the display apparatus 1000 in FIGS. 1 to 10, except for the pixel drive circuit PD, the bonding pattern BP, and a 1-1-th connection line 321a. Therefore, repeated descriptions of the identical components will be omitted or may be briefly provided.

With reference to FIG. 13, the plurality of 1-1-th connection lines 321a can include grooves. The grooves of the plurality of 1-1-th connection lines 321a can be portions corresponding to the groove of the passivation film PDc of the pixel drive circuit PD and be positions at which the bonding pattern BP is disposed.

The bonding pattern BP can be disposed in the grooves of the plurality of 1-1-th connection lines 321a, such that the plurality of 1-1-th connection lines 321a and the plurality of circuit pads PDb can be coupled and electrically connected to one another by means of the bonding pattern BP and simultaneously fix the pixel drive circuit PD. For example, the plurality of 1-1-th connection lines 321a and the plurality of circuit pads PDb can be electrically connected by diffusion bonding. For example, the plurality of 1-1-th connection lines 321a and the plurality of circuit pads PDb can be connected by applying predetermined heat and pressure. However, the present disclosure is not limited thereto.

The plurality of circuit pads PDb can be electrically connected to the 1-1-th connection line 321a through the bonding pattern BP and transmit various signals. For example, the plurality of circuit pads PDb can be disposed inward of the passivation film PDc and coupled to the 1-1-th connection line 321a by means of the bonding pattern of the 1-1-th connection line 321a. However, the present disclosure is not limited thereto. The plurality of circuit pads PDb can be made of an electrically conductive material, e.g., a material containing titanium (Ti). However, the present disclosure is not limited thereto.

The passivation film PDc of the pixel drive circuit PD can be disposed to surround the body PDa and the plurality of circuit pads PDb. For example, the passivation film PDc can include the groove that exposes the plurality of circuit pads PDb. The groove of the passivation film PDc can be disposed to correspond to the groove of the 1-1-th connection line 321a. That is, like the groove of the 1-1-th connection line 321a, the groove of the passivation film PDc can be a position at which the bonding pattern BP is disposed. That is, the bonding pattern BP can be disposed in the groove of the passivation film PDc, such that the circuit pad, which is exposed by the groove, can be bonded to the 1-1-th connection line 321a.

With reference to FIGS. 13 to 14B together, the bonding pattern BP can be disposed between the plurality of 1-1-th connection lines 321a and the pixel drive circuit PD. Specifically, the bonding pattern BP can be disposed between the plurality of 1-1-th connection lines 321a and the plurality of circuit pads PDb of the pixel drive circuit PD in the grooves of the plurality of 1-1-th connection lines 321a and the groove of the passivation film PDc. The bonding pattern BP can electrically connect the plurality of 1-1-th connection lines 321a and the plurality of circuit pads PDb of the pixel drive circuit PD.

For example, the bonding pattern BP can be formed by diffusion bonding between the 1-1-th connection line 321a and the circuit pad PDb. That is, the bonding pattern BP can be formed between the 1-1-th connection line 321a and the circuit pad PDb as a material, which constitutes the 1-1-th connection line 321a, and a material, which constitutes the circuit pad PDb, are diffused toward each other. However, the present disclosure is not limited thereto.

For example, with reference to FIG. 14A, the initial circuit pad PDb′ and an initial 1-1-th connection line 321a′ can have flat structure in which neither a protruding portion nor a groove is disposed. That is, the initial circuit pad PDb′ can be disposed on the same plane as the passivation film PDc and disposed on and adjoin the initial 1-1-th connection line 321a′ in parallel with the initial 1-1-th connection line 321a′. In this case, a material, which constitutes the initial 1-1-th connection line 321a′, can be diffused toward the initial circuit pad PDb′ from the portion of the initial 1-1-th connection line 321a′ that adjoins the initial circuit pad PDb′. Therefore, a thickness of the protruding portion of the initial 1-1-th connection line 321a′ can be decreased, and the groove can be formed. However, the present disclosure is not limited thereto.

Likewise, the material, which constitutes the initial circuit pad PDb′, moves toward the initial 1-1-th connection line 321a′ from the portion of the initial circuit pad PDb′ that adjoins the initial 1-1-th connection line 321a′, such that a thickness of the initial circuit pad PDb′ can be decreased by the diffusion bonding process, and the circuit pad PDb can be disposed inward of the passivation film PDc. However, the present disclosure is not limited thereto.

That is, with reference to FIGS. 14A and 14B, the groove can be formed in the 1-1-th connection line 321a by the thickness of the initial 1-1-th connection line 321a′ that is decreased by the diffusion bonding process. Likewise, the thickness of the circuit pad PDb′ is decreased by the diffusion bonding process, and the circuit pad PDb is disposed inward of the passivation film PDc, such that the groove, which exposes the circuit pad PDb, can be formed from the point of view of the passivation film PDc.

Therefore, the bonding pattern BP can be formed between the groove of the 1-1-th connection line 321a and the groove of the passivation film PDb. Therefore, the bonding pattern BP can be disposed between the 1-1-th connection line 321a and the circuit pad PDb in the groove of the 1-1-th connection line 321a and the groove of the passivation film PDc and simultaneously adjoin the 1-1-th connection line 321a and the circuit pad PDb. Therefore, the bonding pattern BP can simultaneously fix and electrically connect the 1-1-th connection line 321a and the circuit pad PDb.

After the diffusion bonding, the 1-1-th connection line 321a and the circuit pad PDb can be disposed to be spaced apart from each other based on the bonding pattern BP. However, the present disclosure is not limited thereto.

Meanwhile, a thickness of the bonding pattern BP can be determined depending on the thicknesses of the initial 1-1-th connection line 321a′ and the circuit pad PDb′. However, the present disclosure is not limited thereto.

For example, the bonding pattern BP can be made of an intermetallic compound. For example, the bonding pattern BP can be made of an intermetallic compound of a material that constitutes the plurality of 1-1-th connection lines 321a and a material that constitutes the plurality of circuit pads PDb of the pixel drive circuit PD. For example, the bonding pattern BP can be made of titanium aluminide (TiAl₃) in case that the 1-1-th connection line 321a is made of aluminum (Al) and the circuit pad PDb is made of titanium (Ti). However, the present disclosure is not limited thereto.

In the display apparatus 3000 according to still another embodiment of the present disclosure, the pixel drive circuit PD is disposed on the 1-1-th connection line 321a and bonded without a separate bonding layer, such that the pixel drive circuit PD and the 1-1-th connection line 321a can be electrically connected, and the pixel drive circuit PD can be fixed. Specifically, the pixel drive circuit PD can be disposed such that the circuit pad PDb is disposed to be directed downward, such that the pixel drive circuit PD can be disposed on the 1-1-th connection line 321a disposed below the pixel drive circuit PD. For example, in the state in which the circuit pad PDb disposed on the bottom surface of the body PDa of the pixel drive circuit PD is disposed on the same plane as the passivation film PDc, i.e., disposed in parallel with the passivation film PDc, the circuit pad PDb is disposed on the 1-1-th connection line 321a, such that the pixel drive circuit PD can be electrically connected to the 1-1-th connection line 321a while being transferred onto the 1-1-th connection line 321a. In this case, the circuit pad PDb and the 1-1-th connection line 321a can be bonded by diffusion bonding. Therefore, the 1-1-th connection line 321a and the passivation film PDc can have the grooves formed to correspond to each other, and the 1-1-th connection line 321a and the passivation film PDc can be bonded by means of the bonding pattern BP formed between the grooves, such that it is possible to ensure a fixing force made by diffusion bonding.

That is, in the display apparatus 3000 according to still another embodiment of the present disclosure, the pixel drive circuit PD can be effectively fixed onto the substrate 110 without a separate bonding layer, and the bonding layer can be excluded, which can reduce the process time and costs. In addition, because the bonding layer is excluded, it is possible to suppress a defect caused when unnecessary foreign substances are attached to the bonding layer. Therefore, because a process of removing foreign substances can also be excluded, which can more effectively reduce the process time and costs.

In addition, in the display apparatus 3000 according to still another embodiment of the present disclosure, the layered structure can be further simplified by excluding the bonding layer. Therefore, a thin display apparatus can be implemented, and various constituent elements can be stacked to minimize a problem of a deterioration in flatness of the upper portion of the substrate 110, such that the flatness of the display apparatus 3000 can be ensured.

In addition, because the pixel drive circuit PD is disposed on the 1-1-th connection line 321a made of a metallic material, the 1-1-th connection line 321a can be utilized as an alignment key. Therefore, it is possible to reduce the process time and costs because a process of separately forming an alignment key made of a metallic material to align the position of the pixel drive circuit PD can be excluded.

Further, in the display apparatus 3000 according to still another embodiment of the present disclosure, the 1-1-th connection line 321a and the 1-2-th connection line 121b can be disposed to be spaced apart from each other based on the pixel drive circuit PD and the protective layer 112 that surrounds the pixel drive circuit PD. That is, because the 1-2-th connection line 121b is disposed on the protective layer 112 basically disposed to planarize the pixel drive circuit PD and the peripheral area, a separate additional protective layer or insulation layer does not need to be disposed between the 1-1-th connection line 321a and the 1-2-th connection line 121b. Therefore, it is possible to reduce the process costs and time that can be incurred by an arrangement of an additional protective layer or insulation layer. In addition, the layered structure can be minimized by excluding an additional protective layer or insulation layer, such that a thin display apparatus can be implemented, and the flatness of the upper portion of the substrate 110 can be ensured.

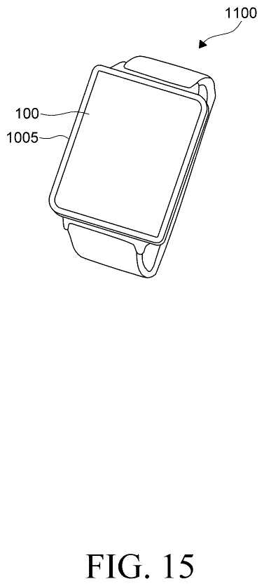

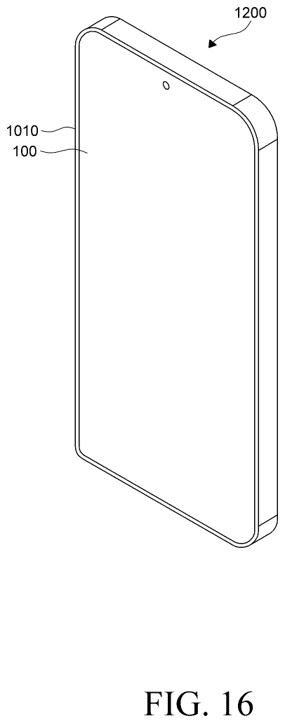

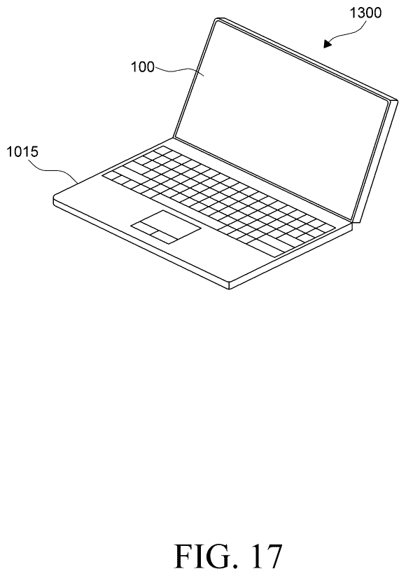

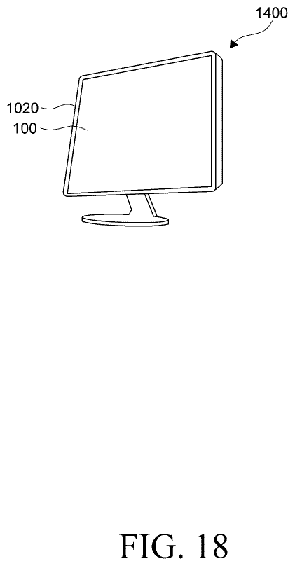

FIGS. 15 to 18 are views illustrating apparatuses to which the display apparatus according to the embodiments of the present disclosure are applied.

Referring to FIGS. 15 to 18, the display apparatus 1000, 2000 and 3000 according to the example embodiments of the present disclosure can be included in various apparatuses or electronic apparatuses. For example, referring to FIGS. 15 to 18, various electronic apparatuses can include a wearable device 1100, a mobile device 1200, a laptop 1300, and a monitor, or TV 1400, but the example embodiments of the present disclosure are not limited thereto.

Each of the wearable device 1100, the mobile device 1200, the laptop 1300, and the monitor or the TV 1400 can include case parts 1005, 1010, 1015, and 1020 and the display panel 100 and the display apparatus 1000, 2000 and 3000 according to the example embodiments of the present disclosure described in FIGS. 1 to 14B.

For example, the display apparatus according to example embodiments of the present disclosure can be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical apparatus, a desktop PC, a laptop PC, a netbook computer, a workstation, a navigation system, a vehicle display apparatus, a theater display apparatus, a television, a wallpaper apparatus, a signage apparatus, a game console, a laptop, a monitor, a camera, a camcorder, home appliances, etc.

The example embodiments of the present disclosure can also be described as follows:

According to an aspect of the present disclosure, there is provided a display apparatus. The display apparatus includes a substrate including a display area, and a non-display area configured to surround the display area, a buffer layer disposed on the substrate, a plurality of 1-1-th connection lines disposed on the buffer layer in the display area, a pixel drive circuit disposed on the plurality of 1-1-th connection lines and including a body, a plurality of circuit pads disposed on a bottom surface of the body, and a passivation film disposed to surround the body and the plurality of circuit pads, a plurality of bonding patterns configured to connect the plurality of 1-1-th connection lines and the plurality of circuit pads, a bank disposed on the pixel drive circuit and a plurality of micro-LEDs disposed on the bank and electrically connected to the pixel drive circuit.

The plurality of 1-1-th connection lines can include grooves, and the plurality of circuit pads can protrude further than the passivation film and can be respectively disposed in the grooves of the plurality of 1-1-th connection lines.

The plurality of bonding patterns can be disposed between the plurality of 1-1-th connection lines and the plurality of circuit pads in the grooves of the plurality of 1-1-th connection lines.

The passivation film can include a groove configured to expose the plurality of circuit pads, and the plurality of 1-1-th connection lines can include protruding portions disposed in the groove of the passivation film.

The plurality of bonding patterns can be disposed between the plurality of 1-1-th connection lines and the plurality of circuit pads in the groove of the passivation film.

The plurality of 1-1-th connection lines can include grooves, the passivation film can include a groove configured to expose the plurality of circuit pads, and the grooves of the plurality of 1-1-th connection lines can be disposed to correspond to the groove of the passivation film.

The plurality of bonding patterns can be disposed between the plurality of 1-1-th connection lines and the plurality of circuit pads in the grooves of the plurality of 1-1-th connection lines and the groove of the passivation film.

The plurality of 1-1-th connection lines and the plurality of circuit pads can be electrically connected by diffusion bonding.

The plurality of bonding patterns can be formed by diffusion bonding between the plurality of 1-1-th connection lines and the plurality of circuit pads.

The plurality of bonding patterns can be made of an intermetallic compound of a material that constitutes the plurality of 1-1-th connection lines and a material that constitutes the plurality of circuit pads.

The plurality of 1-1-th connection lines can be made of aluminum (Al), the plurality of circuit pads can be made of titanium (Ti), and the plurality of bonding patterns can be made of titanium aluminide (TiAl₃).

The display apparatus can further include a protective layer disposed to surround the pixel drive circuit and a plurality of 1-2-th connection lines disposed on the protective layer. The plurality of 1-2-th connection lines can be connected to the plurality of 1-1-th connection lines through a contact hole of the protective layer.

The non-display area can include a first non-display area disposed to surround the display area, a bending area extending from the first non-display area and a second non-display area extending from the bending area. The display apparatus can further include a second connection line disposed on the substrate, disposed in the display area and the first non-display area, the bending area and the second non-display area, and electrically connected to the pixel drive circuit. The second connection line can partially adjoin the buffer layer in the display area, the first non-display area, and the second non-display area and can adjoin the substrate in the bending area.

The plurality of micro-LEDs each can include an anode electrode, a first semiconductor layer disposed on the anode electrode, an active layer disposed on the first semiconductor layer, a second semiconductor layer disposed on the active layer and a cathode electrode disposed on the second semiconductor layer.

The display apparatus can further include a first electrode disposed below the plurality of micro-LEDs and configured to electrically connect the pixel drive circuit and the anode electrode of each of the plurality of micro-LEDs and a solder pattern disposed between the first electrode and the anode electrode. The first electrode and the anode electrode can be electrically connected by eutectic bonding using the solder pattern.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display apparatus comprising:
a substrate including a display area and a non-display area adjacent to the display area;
a buffer layer disposed on the substrate;
a plurality of 1-1-th connection lines disposed on the buffer layer in the display area;
a pixel drive circuit disposed on the plurality of 1-1-th connection lines, wherein the pixel drive circuit includes a body, a plurality of circuit pads disposed on a bottom surface of the body, and a passivation film disposed to surround the body and the plurality of circuit pads;
a plurality of bonding patterns configured to connect the plurality of 1-1-th connection lines and the plurality of circuit pads;
a bank disposed on the pixel drive circuit; and
a plurality of micro-light emitting diodes (micro-LEDs) disposed on the bank and electrically connected to the pixel drive circuit.

2. The display apparatus of claim 1, wherein the plurality of 1-1-th connection lines include grooves, and
wherein the plurality of circuit pads protrude further than the passivation film and are respectively disposed in the grooves of the plurality of 1-1-th connection lines.

3. The display apparatus of claim 2, wherein the plurality of bonding patterns are disposed between the plurality of 1-1-th connection lines and the plurality of circuit pads in the grooves of the plurality of 1-1-th connection lines.

4. The display apparatus of claim 1, wherein the passivation film includes a groove configured to expose the plurality of circuit pads, and the plurality of 1-1-th connection lines include protruding portions disposed in the groove of the passivation film.

5. The display apparatus of claim 4, wherein the plurality of bonding patterns are disposed between the plurality of 1-1-th connection lines and the plurality of circuit pads in the groove of the passivation film.

6. The display apparatus of claim 1, wherein the plurality of 1-1-th connection lines include grooves,
wherein the passivation film includes a groove configured to expose the plurality of circuit pads, and
wherein the grooves of the plurality of 1-1-th connection lines are disposed to correspond to the groove of the passivation film.

7. The display apparatus of claim 6, wherein the plurality of bonding patterns are disposed between the plurality of 1-1-th connection lines and the plurality of circuit pads in the grooves of the plurality of 1-1-th connection lines and the groove of the passivation film.

8. The display apparatus of claim 1, wherein the plurality of 1-1-th connection lines and the plurality of circuit pads are electrically connected by diffusion bonding.

9. The display apparatus of claim 1, wherein the plurality of bonding patterns are formed by diffusion bonding between the plurality of 1-1-th connection lines and the plurality of circuit pads.

10. The display apparatus of claim 1, wherein the plurality of bonding patterns include an intermetallic compound of a material that constitutes the plurality of 1-1-th connection lines and a material that constitutes the plurality of circuit pads.

11. The display apparatus of claim 10, wherein the plurality of 1-1-th connection lines include aluminum (Al),
wherein the plurality of circuit pads include titanium (Ti), and
wherein the plurality of bonding patterns include titanium aluminide (TiAl₃).

12. The display apparatus of claim 1, further comprising:
a protective layer disposed to surround the pixel drive circuit; and
a plurality of 1-2-th connection lines disposed on the protective layer,
wherein the plurality of 1-2-th connection lines are connected to the plurality of 1-1-th connection lines through a contact hole of the protective layer.

13. The display apparatus of claim 1, wherein the non-display area includes:
a first non-display area disposed to surround the display area;
a bending area extending from the first non-display area; and
a second non-display area extending from the bending area,
wherein the display apparatus further includes a second connection line disposed on the substrate, disposed in the display area and the first non-display area, the bending area and the second non-display area, and electrically connected to the pixel drive circuit.

14. The display apparatus of claim 13, wherein the second connection line partially adjoins the buffer layer in the display area, the first non-display area, and the second non-display area, and adjoins the substrate in the bending area.

15. The display apparatus of claim 1, wherein each of the plurality of micro-LEDs includes:
an anode electrode;
a first semiconductor layer disposed on the anode electrode;
an active layer disposed on the first semiconductor layer;
a second semiconductor layer disposed on the active layer; and
a cathode electrode disposed on the second semiconductor layer.

16. The display apparatus of claim 15, further comprising:
a first electrode disposed below the plurality of micro-LEDs and configured to electrically connect the pixel drive circuit and the anode electrode of each of the plurality of micro-LEDs; and
a solder pattern disposed between the first electrode and the anode electrode,
wherein the first electrode and the anode electrode are electrically connected by eutectic bonding using the solder pattern.

17. The display apparatus of claim 1, wherein the display apparatus is part of a wearable device, a mobile device, a laptop, a monitor, or a television.

18. A display apparatus comprising:
a substrate including a display area and a non-display area separate from the display area;
a plurality of connection lines disposed in the display area;
a pixel drive circuit disposed on the plurality of connection lines, wherein the pixel drive circuit includes a body, a plurality of circuit pads disposed on a lower surface of the body, and a passivation film disposed to support the body and the plurality of circuit pads;
a plurality of bonding patterns configured to connect the plurality of connection lines and the plurality of circuit pads; and
a plurality of micro-light emitting diodes electrically connected to the pixel drive circuit.

19. The display apparatus of claim 18, wherein the plurality of connection lines include grooves, and the plurality of circuit pads are respectively disposed in the grooves of the plurality of connection lines.

20. The display apparatus of claim 18, wherein the plurality of bonding patterns are formed by diffusion bonding between the plurality of connection lines and the plurality of circuit pads.
